(19) United States
(12) Patent Application Publication
(10) Pub. No.: US 2025/0300112 A1
(43) Pub. Date: Sep. 25, 2025

(54) INTEGRATED DEVICE COMPRISING EXTENDED METALLIZATION REGION FOR PILLAR INTERCONNECTS

(71) Applicant: QUALCOMM Incorporated, San Diego, CA (US)

(72) Inventors: Aniket PATIL, San Diego, CA (US); Dongming HE, San Diego, CA (US); Durodami LISK, San Diego, CA (US)

(21) Appl. No.: 18/609,555

(22) Filed: Mar. 19, 2024

(51) Int. Cl. H01L 23/00; H01L 23/31; H01L 23/498

(52) U.S. Cl. CPC H01L 24/16; H01L 23/31; H01L 23/49838; H01L 24/94; H01L 2224/16227; H01L 2224/94; H01L 2924/1431

(57) ABSTRACT

An integrated device comprising a die substrate; a die interconnection portion coupled to the die substrate, wherein the die interconnection portion comprises: at least one die dielectric layer; and a plurality of die interconnects, wherein the die interconnection portion comprises: an inner die interconnection portion; and a periphery die interconnection portion, wherein the periphery die interconnect portion is free of the plurality of die interconnects; a plurality of pad interconnects coupled to the die interconnection portion; a plurality of metallization interconnects coupled to the plurality of pad interconnects, wherein at least one metallization interconnect from the plurality of metallization interconnects, vertically overlaps with the periphery die interconnection portion, and a plurality of pillar interconnects coupled to the plurality of metallization interconnects.

### FIELD

Various features relate to integrated devices.

### BACKGROUND

A package may include a substrate and integrated devices. These components are coupled together to provide a package that may perform various electrical functions. The performance of integrated devices and/or packages and its components may depend on various factors, including the number of interconnects in the packages and/or the integrated devices. There is an ongoing need to improve the performance of integrated devices and/or packages, while also improving and keeping the form factor of integrated devices and/or packages as small as possible.

### SUMMARY

Various features relate to integrated devices.

One example provides an integrated device comprising a die substrate; a die interconnection portion coupled to the die substrate, wherein the die interconnection portion comprises: at least one die dielectric layer; and a plurality of die interconnects, wherein the die interconnection portion comprises: an inner die interconnection portion; and a periphery die interconnection portion, wherein the periphery die interconnect portion is free of the plurality of die interconnects; a plurality of pad interconnects coupled to the die interconnection portion; a plurality of metallization interconnects coupled to the plurality of pad interconnects, wherein at least one metallization interconnect from the plurality of metallization interconnects, vertically overlaps with the periphery die interconnection portion, and a plurality of pillar interconnects coupled to the plurality of metallization interconnects.

Another example provides an integrated device comprising a die substrate; a die interconnection portion coupled to the die substrate, wherein the die interconnection portion comprises: at least one die dielectric layer; and a plurality of die interconnects, a plurality of pad interconnects coupled to the die interconnection portion; an encapsulation layer coupled to (i) a side surface of the die substrate and (ii) a side surface of the die interconnection portion; a plurality of metallization interconnects coupled to the plurality of pad interconnects, wherein at least one metallization interconnect from the plurality of metallization interconnect vertically overlaps with the encapsulation layer, and a plurality of pillar interconnects coupled to the plurality of metallization interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary integrated device that includes pillar interconnects.

FIG. 2 illustrates a cross sectional profile view of an exemplary integrated device that includes pillar interconnects.

FIG. 3 illustrates a plan view of an exemplary integrated device that includes pillar interconnects.

FIG. 4 illustrates a cross sectional profile view of an exemplary package that includes a substrate and an integrated device that includes pillar interconnects.

FIG. 5 illustrates a cross sectional profile view of an exemplary integrated device that includes pillar interconnects.

FIG. 6 illustrates a cross sectional profile view of an exemplary integrated device that includes pillar interconnects.

FIG. 7 illustrates a plan view of an exemplary integrated device that includes pillar interconnects.

FIGS. 8A-8E illustrate an exemplary sequence for fabricating an integrated device that includes pillar interconnects.

FIG. 9 illustrates an exemplary flow diagram of a method for fabricating an integrated device that includes pillar interconnects.

FIGS. 10A-10G illustrate an exemplary sequence for fabricating an integrated device that includes pillar interconnects.

FIG. 11 illustrates an exemplary flow diagram of a method for fabricating an integrated device that includes pillar interconnects.

FIG. 12 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package that includes a substrate and an integrated device coupled to the substrate through a plurality of solder interconnects. The integrated device comprises a die substrate; a die interconnection portion coupled to the die substrate, wherein the die interconnection portion comprises: at least one die dielectric layer; and a plurality of die interconnects. The die interconnection portion comprises an inner die interconnection portion; and a periphery die interconnection portion, wherein the periphery die interconnect portion is free of the plurality of die interconnects. The integrated device further comprises a plurality of pad interconnects coupled to the die interconnection portion; and a plurality of metallization interconnects coupled to the plurality of pad interconnects, wherein at least one metallization interconnect from the plurality of metallization interconnects, vertically overlaps with the periphery die interconnection portion. The integrated device also includes a plurality of pillar interconnects coupled to the plurality of metallization interconnects. The use of a periphery region of the integrated device that does not include any die interconnects, allows more pillar interconnects to be formed with the integrated device. Utilizing a region of the integrated device that would otherwise not be used for providing electrical paths, may help improve the performance of the integrated device, while keeping the form factor of the integrated device as compact as possible.

### Exemplary Integrated Devices Comprising Periphery Region Configured for Coupling to Pillar Interconnects

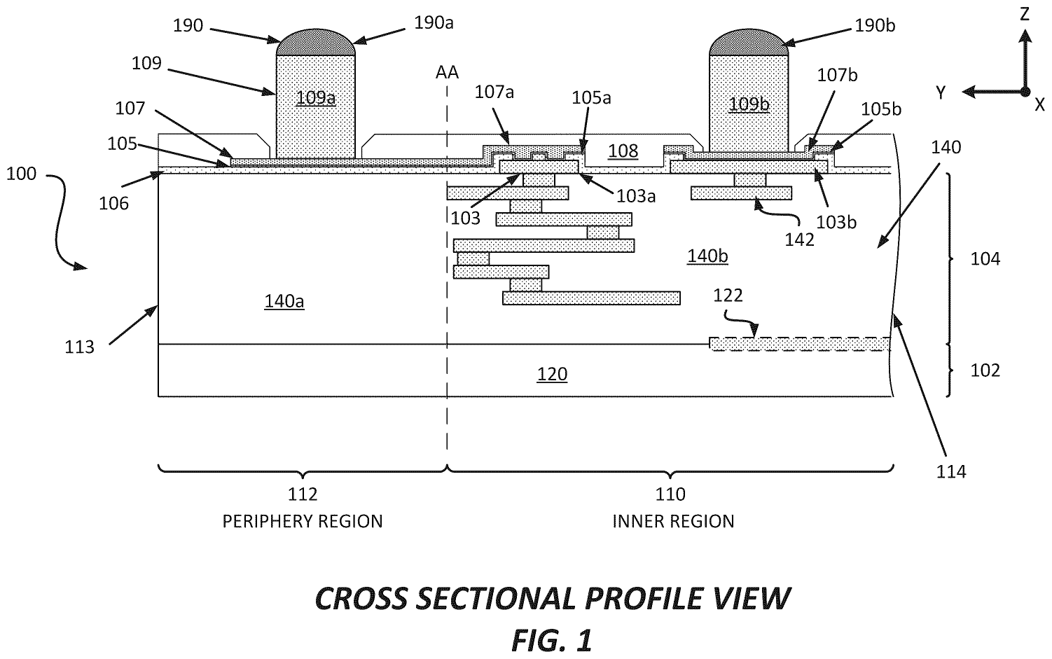

FIG. 1 illustrates a cross sectional profile view of an integrated device 100 that includes pillar interconnects, where some of the pillar interconnects are located in a periphery region of the integrated device 100. The integrated device 100 includes a die substrate portion 102, a die interconnection portion 104, a plurality of pad interconnects 103, a plurality of seed layers 105, a plurality of metallization interconnects 107, a plurality of pillar interconnects 109, a plurality of solder interconnects 190, a passivation layer 106 and a passivation layer 108. The integrated device 100 includes an inner region 110 and a periphery region 112. As will be further described below, the periphery region 112 of the integrated device 100 may be configured to provide a region of the integrated device 100 that a pillar interconnect may couple with and vertically overlap with.

The die substrate portion 102 includes a die substrate 120 and an active region 122. The die substrate 120 may include silicon (Si). The active region 122 may be formed in the die substrate 120 and/or a surface of the die substrate 120. The active region 122 may include a plurality of logic cells and/or a plurality of transistors. One or more transistors may define a logic cell. The plurality of logic cells may include functioning logic cells when the integrated device is in operation. The plurality of transistors may include functioning transistors. Different implementations may use different types of transistors, such as a field effect transistor (FET), planar FET, finFET, and a gate all around FET. In some implementations, a front end of line (FEOL) process may be used to fabricate the plurality of cells and/or transistors in and/or over the die substrate 120. In some implementations, the die substrate portion 102 may include a plurality of through substrate vias (not shown) that extend through the die substrate 120. A back side metallization portion (not shown) may be coupled to the die substrate 120. The back side metallization portion may include a plurality of back side metallization interconnects that are coupled to the through substrate vias that extend through the die substrate 120. A portion of the die substrate 120 may be located in the inner region 110 of the integrated device 100 and another portion of the die substrate 120 may be located in the periphery region 112 of the integrated device 100. The active region 122 of the die substrate portion 102 may be located in the inner region 110 of the integrated device 100.

The die interconnection portion 104 is coupled to the die substrate portion 102. For example, the die interconnection portion 104 is coupled to the die substrate 120. The die interconnection portion 104 includes at least one dielectric layer 140 and a plurality of die interconnects 142. The interconnection portion 104 may be configured to be electrically coupled to the active region 122. For example, the plurality of die interconnects 142 may be configured to be electrically coupled to the active region 122. Thus, the plurality of die interconnects 142 may be configured to be electrically coupled to the plurality of logic cells and/or plurality of transistors. In some implementations, a back end of line (BEOL) process may be used to fabricate the die interconnection portion 104. The die interconnection portion 104 may be a BEOL die interconnection portion. The plurality of die interconnects 142 may include copper (Cu).

A portion of the die interconnection portion 104 may be located in the inner region 110. Another portion of the die interconnection portion 104 may be located in the periphery region 112. The at least one dielectric layer 140 may include at least one dielectric layer 140a and at least one dielectric layer 140b. The at least one dielectric layer 140a and the at least one dielectric layer 140b may be a continuous and/or contiguous dielectric layer. In some implementations, the at least one dielectric layer 140a may be considered a first portion of the at least one dielectric layer 140, and the at least one dielectric layer 140b may be considered a second portion of the at least one dielectric layer 140. The at least one dielectric layer 140a may be located in the periphery region 112 of the integrated device 100. The at least one dielectric layer 140b may be located in the inner region 110 of the integrated device 100. The plurality of die interconnects 142 may be located in the inner region 110 of the integrated device 100. The region of the die interconnection region 140 that is located in the inner region 110 may be an inner die interconnection region 114. The region of the die interconnection region 140 that is located in the periphery region 112 may be a periphery die interconnection region 113. In some implementations, the periphery die interconnection region 113 may be free of the plurality of die interconnects 142. The inner region 110 of the integrated device 100 may be defined as a region that includes the plurality of die interconnects 142 and/or the active region 122. In some implementations, the periphery region 112 of the integrated device 100 may be defined as a region along the edges of the integrated device 100, that is free of the plurality of die interconnects 142 and free of the active region 122.

The plurality of pad interconnects 103 are coupled to the die interconnection portion 104. The plurality of pad interconnects 103 may be coupled to the plurality of die interconnects 142. The plurality of pad interconnects 103 may include Aluminum (Al). The plurality of pad interconnects 103 may be located in the inner region 110 of the integrated device 100.

The passivation layer 106 is coupled to the die interconnection portion 104. The passivation layer 106 may be formed and coupled to a surface of the die interconnection portion 104. The passivation layer 106 may be coupled to and touch the at least one dielectric layer 140. The passivation layer 106 may be formed and coupled to part of the plurality of pad interconnects 103. The passivation layer 106 may include silicon nitride (SiN). A portion of the passivation layer 106 may be located in the inner region 110 of the integrated device 100. Another portion of the passivation layer 106 may located in the periphery region 112 of the integrated device 100.

The plurality of seed layers 105 are formed and coupled to the plurality of pad interconnects 103 and the passivation layer 106. The plurality of seed layers 105 may include copper (e.g., Cu). A portion of the plurality of seed layers 105 may be located in the inner region 110 of the integrated device 100. Another portion of the plurality of seed layers 105 may be located in the periphery region 112 of the integrated device 100.

The plurality of metallization interconnects 107 may be coupled to the plurality of seed layers 105. In some implementations, the plurality of seed layers 105 may be indistinguishable from the plurality of metallization interconnects 107. In some implementations, the plurality of seed layers 105 may be considered part of the plurality of metallization interconnects 107. The plurality of metallization interconnects 107 may include copper (Cu). The plurality of metallization interconnects 107 may be coupled to the plurality of pad interconnects 103. A portion of the plurality of metallization interconnects 107 may be located in the inner region 110 of the integrated device 100. Another portion of the plurality of metallization interconnects 107 may be located in the periphery region 112 of the integrated device 100. The plurality of metallization interconnects 107 may include a plurality of redistribution interconnects.

The passivation layer 108 may be coupled to the passivation layer 106 and the plurality of metallization interconnects 107. The passivation layer 108 may include polyimide. The plurality of pillar interconnects 109 may be coupled to the plurality of metallization interconnects 107. Some of the pillar interconnects from the plurality of pillar interconnects 109 may be located in the inner region 110 of the integrated device 100. Other pillar interconnects from the plurality of pillar interconnects 109 may be located in the periphery region 112 of the integrated device 100. The plurality of pillar interconnects 109 may include copper (Cu). The plurality of solder interconnects 190 may be coupled to the plurality of pillar interconnects 109.

In some implementations, a back end of line (BEOL) process may be used to fabricate the die interconnection portion 104, the passivation layer 106, and/or the plurality of pad interconnects 103.

The plurality of pad interconnects 103 includes a pad interconnect 103a (e.g., first pad interconnect) and a pad interconnect 103b (e.g., second pad interconnect). The plurality of seed layer 105 includes a seed layer 105a and a seed layer 105b. The plurality of metallization interconnects 107 may include a metallization interconnect 107a (e.g., first metallization interconnect) and a metallization interconnect 107b (e.g., second metallization interconnect). The plurality of pillar interconnects 109 includes a pillar interconnect 109a (e.g., first pillar interconnect) and a pillar interconnect 109b (e.g., second pillar interconnect).

The pad interconnect 103a and the pad interconnect 103b are located in the inner region 110 of the integrated device 100. The pad interconnect 103a and the pad interconnect 103b vertically overlap with the inner die interconnection portion 114. The pad interconnect 103a is coupled to a first die interconnect from the plurality of die interconnects 142. The pad interconnect 103b is coupled to a second die interconnect from the plurality of die interconnects 142.

The seed layer 105a is coupled to the pad interconnect 103a. The metallization interconnect 107a is coupled to the seed layer 105a. The seed layer 105a may be considered part of the metallization interconnect 107a. Thus, the metallization interconnect 107a may be considered to be coupled to the pad interconnect 103a. The metallization interconnect 107a is coupled to the pillar interconnect 109a. The solder interconnect 190a is coupled to the pillar interconnect 109a.

The seed layer 105b is coupled to the pad interconnect 103b. The metallization interconnect 107b is coupled to the seed layer 105b. The seed layer 105b may be considered part of the metallization interconnect 107b. Thus, the metallization interconnect 107b may be considered to be coupled to the pad interconnect 103b. The metallization interconnect 107b is coupled to the pillar interconnect 109b. The solder interconnect 190b is coupled to the pillar interconnect 109b.

The pillar interconnect 109a and the solder interconnect 190a may vertically overlap with the periphery region 112 of the integrated device 100. A portion of the seed layer 105a and a portion of the metallization interconnect 107a may be located in the periphery region 112 of the integrated device 100. In some implementations, the pillar interconnect 109a and the solder interconnect 190a may be considered to be located in the periphery region 112 of the integrated device 100. The pillar interconnect 109a and the solder interconnect 190a may not vertically overlap with the plurality of die interconnects 142 of the die interconnection portion 104. The pillar interconnect 109a and the solder interconnect 190a may not vertically overlap with the active region 122 of the die substrate portion 102. In some implementations, the periphery region 112 may include dummy transistors. These dummy transistors may not operate when the integrated device 100 is in operation. It is noted that a dummy transistor is different from a defective transistor. A defective transistor is a transistor that is configured to function when the integrated device 100 is in operation, but for some reason, does not function and/or does not function properly. In some implementations, part of the plurality of die interconnects 142 may extend into the periphery region 112. These die interconnects that extend into the periphery region 112, may be configured to be coupled to testing structures. These die interconnects that extend in the periphery region 112 may be dead end die interconnects (e.g., dead end terminal die interconnect) that may no longer directly be coupled to and touch a pad interconnect in the periphery region 112. The dead end die interconnects may be used when testing a wafer, but may no longer be in use after singulation. The pillar interconnect 109a and/or the solder interconnect 190a may vertically overlap with dead end die interconnects in the periphery region 112.

Another portion of the seed layer 105a and another portion of the metallization interconnect 107a may be located in the inner region 110 of the integrated device 100. The seed layer 105b, the metallization interconnect 107b, the pillar interconnect 109b and the solder interconnect 190b may be considered to be located in the inner region 110 of the integrated device 100. The pillar interconnect 109b and the solder interconnect 190b may vertically overlap with the plurality of die interconnects 142. In some implementations, the pillar interconnect 109b and the solder interconnect 190b may vertically overlap with the active region 122.

FIG. 1 illustrates an integrated device that utilizes a region that would otherwise not be used. In particular, the integrated device 100 provides a periphery region 112 that may be free of the plurality of die interconnects and free of the active region 122, which allows more electrical paths to and/or from the integrated device, which can lead to improved performance of the integrated device 100. In addition, the additional space means that the pitch between pillar interconnects do not need to be as small, which can provide improved yields during the manufacturing of the integrated device 100. This can result in a lower cost for the manufacturing of the integrated device 100.

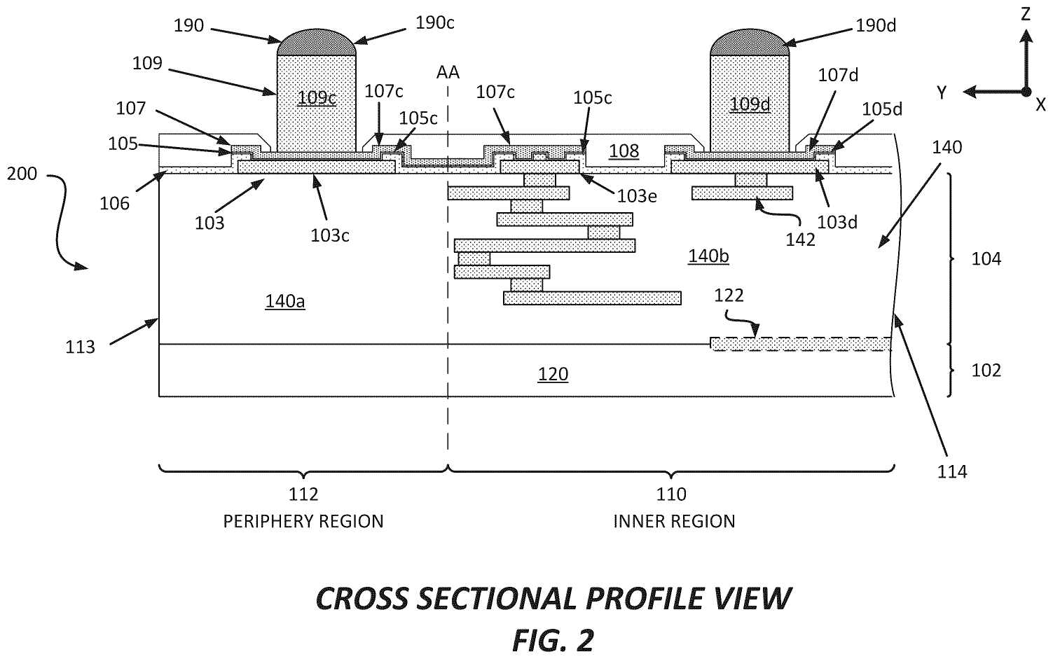

FIG. 2 illustrates a cross sectional profile view of an integrated device 200 that includes pillar interconnects, where some of the pillar interconnects are located in a periphery region of the integrated device 200. The integrated device 200 is similar to the integrated device 100 of FIG. 1, and includes similar components that are arranged in a similar manner as described for the integrated device 100. The integrated device 200 illustrates at least one pad interconnect (e.g., 103c) that is located in a periphery region of the integrated device 200, where the periphery region may be free of a plurality of die interconnects and free of an active region. The integrated device 200 includes a die substrate portion 102, a die interconnection portion 104, a plurality of pad interconnects 103, a plurality of seed layers 105, a plurality of metallization interconnects 107, a plurality of pillar interconnects 109, a plurality of solder interconnects 190, a passivation layer 106 and a passivation layer 108. The integrated device 100 includes an inner region 110 and a periphery region 112.

The die substrate portion 102 and the die interconnection portion 104 of the integrated device 200 may be similar to the die substrate portion 102 and the die interconnection portion 104 of the integrated device 100. As shown in FIG. 2, the plurality of pad interconnects 103 includes a pad interconnect 103c (e.g., first pad interconnect), a pad interconnect 103d (e.g., second pad interconnect) and a pad interconnect 103e (e.g., third pad interconnect). The plurality of seed layer 105 includes a seed layer 105c and a seed layer 105d. The plurality of metallization interconnects 107 may include a metallization interconnect 107c (e.g., first metallization interconnect) and a metallization interconnect 107d (e.g., second metallization interconnect). The plurality of pillar interconnects 109 includes a pillar interconnect 109c (e.g., first pillar interconnect) and a pillar interconnect 109d (e.g., second pillar interconnect).

The pad interconnect 103d and the pad interconnect 103e are located in the inner region 110 of the integrated device 100. The pad interconnect 103d and the pad interconnect 103e vertically overlap with the inner die interconnection portion 114. The pad interconnect 103c are located in the periphery region 112. The pad interconnect 103c may vertically overlap with the periphery die interconnect portion 113, where the periphery die interconnect portion 113 may be free of the plurality of die interconnects 142. The pad interconnect 103c does not vertically overlap with the plurality of die interconnects 142. The pad interconnect 103c does not vertically overlap with the Active region 122. The pad interconnect 103e is coupled to a first die interconnect from the plurality of die interconnects 142. The pad interconnect 103d is coupled to a second die interconnect from the plurality of die interconnects 142. The pad interconnect 103c is not in direct contact with any of the plurality of die interconnects 142.

The seed layer 105c is coupled to the pad interconnect 103c and the pad interconnect 103e. The metallization interconnect 107c is coupled to the seed layer 105c. The seed layer 105c may be considered part of the metallization interconnect 107c. Thus, the metallization interconnect 107c may be considered to be coupled to the pad interconnect 103c and the pad interconnect 103e. The metallization interconnect 107c is coupled to the pillar interconnect 109c. The solder interconnect 190c is coupled to the pillar interconnect 109c.

The seed layer 105d is coupled to the pad interconnect 103d. The metallization interconnect 107d is coupled to the seed layer 105d. The seed layer 105d may be considered part of the metallization interconnect 107d. Thus, the metallization interconnect 107d may be considered to be coupled to the pad interconnect 103d. The metallization interconnect 107d is coupled to the pillar interconnect 109d. The solder interconnect 190d is coupled to the pillar interconnect 109d.

The pillar interconnect 109c and the solder interconnect 190c may vertically overlap with the periphery region 112 of the integrated device 100. The pillar interconnect 109c and the solder interconnect 190c may vertically overlap with the pad interconnect 103c. A portion of the seed layer 105c and a portion of the metallization interconnect 107c may be located in the periphery region 112 of the integrated device 100. In some implementations, the pillar interconnect 109c and the solder interconnect 190c may be considered to be located in the periphery region 112 of the integrated device 100. The pillar interconnect 109c and the solder interconnect 190c may not vertically overlap with the plurality of die interconnects 142 of the die interconnection portion 104. The pillar interconnect 109c and the solder interconnect 190c may not vertically overlap with the active region 122 of the die substrate portion 102. In some implementations, the periphery region 112 may include dummy transistors. These dummy transistors may not operate when the integrated device 100 is in operation. In some implementations, part of the plurality of die interconnects 142 may extend into the periphery region 112. These die interconnects that extend into the periphery region 112, may be configured to be coupled to testing structures. These die interconnects that extend in the periphery region 112 may be dead end die interconnects (e.g., dead end terminal die interconnect) that may no longer directly be coupled to and touch a pad interconnect in the periphery region 112. The dead end die interconnects may be used when testing a wafer, but may no longer be in use after singulation. The pad interconnect 103c, the pillar interconnect 109c and/or the solder interconnect 190c may vertically overlap with dead end die interconnects in the periphery region 112.

Another portion of the seed layer 105c and another portion of the metallization interconnect 107c may be located in the inner region 110 of the integrated device 100. The seed layer 105d, the metallization interconnect 107d, the pillar interconnect 109d and the solder interconnect 190d may be considered to be located in the inner region 110 of the integrated device 100. The pillar interconnect 109d and the solder interconnect 190d may vertically overlap with the plurality of die interconnects 142. In some implementations, the pillar interconnect 109d and the solder interconnect 190d may vertically overlap with the active region 122.

In some implementations, an integrated device (e.g., 100, 200) may include one or more alignment markers. These alignment markers may be alignment interconnects. These alignment markers may help a device, a machine and/or a system for singulating a wafer into integrated devices. Such a device, a machine and/or a system may use the alignment markers so that the laser and/or saw that singulates the wafer, cuts in the proper regions of the wafer. For example, the device, the machine and/or the system may singulate wafers between two alignment markers. These alignment markers may have a specific shape that indicate that they are alignment markers. An optical system may be used to identify these alignment markers. These alignment markers may be located in a region that is planar to the plurality of metallization interconnects 107, the plurality of pad interconnects 103 and/or the plurality of die interconnects 142. In some implementations, the boundary AA between the periphery region and the inner region may be defined by these alignment markers. For example, the vertical boundary (e.g., boundary wall) between the periphery region and the inner region of an integrated device may be defined by one or more alignment markers. Thus, one or more alignment markers may be located on or about the boundary AA between the periphery region 112 and the inner region 110 of an integrated device (e.g., 100, 200). In some implementations, the plurality of pad interconnects 103 may be located on both sides (e.g., to the left and to the right) of these alignment markers. In some implementations, the plurality of pillar interconnects 109 may be located on both sides (e.g., to the left and to the right) of these alignment markers. However, one or more alignment markers may not be located on the boundary AA. In some implementations, the periphery region 112 of the integrated device (e.g., 100, 200) may be defined as a region between a particular edge of the integrated device and a particular alignment marker that is nearest to the particular edge.

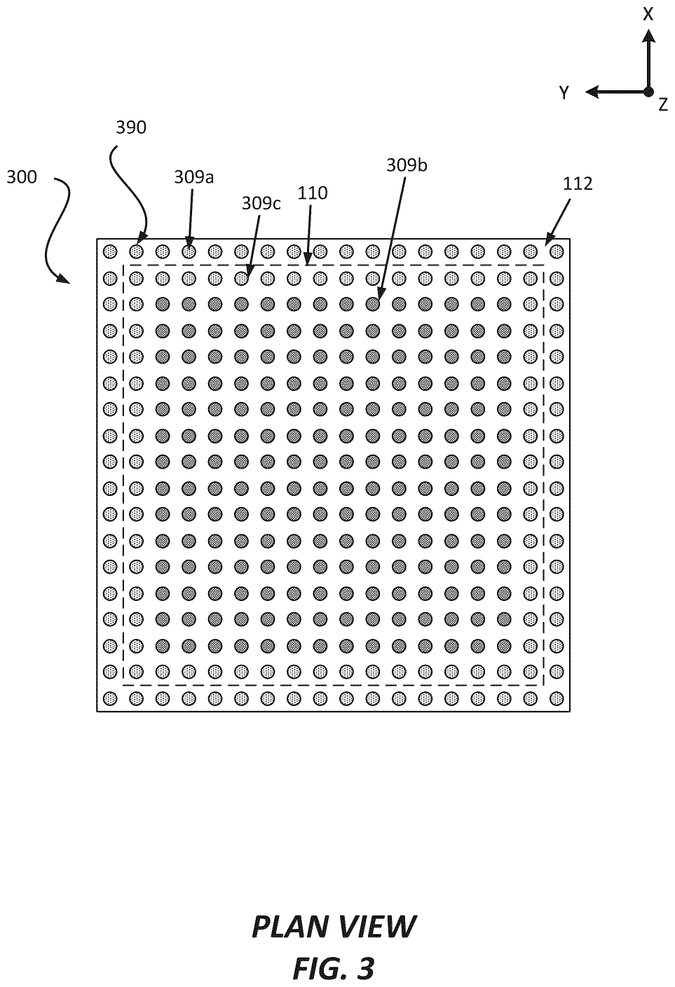

FIG. 3 illustrates a plan view of the integrated device 300. The integrated device 300 may represent any of the integrated devices described in the disclosure. For example, the integrated device 300 may represent the integrated device 100, the integrated device 200, the integrated device 500 and/or the integrated device 600. The integrated device 300 includes an inner region 110 and a periphery region 112. The periphery region 112 may be located along the edges of the integrated device 300. In some implementations, the periphery region 112 may be a region that is within a range of about 100-500 micrometers from an edge of the integrated device 300. In some implementations, the periphery region 112 may be free of any active regions (e.g., free of logic cells and/or transistors) and free of die interconnects in the die interconnection portion 104. In some implementations, the periphery die interconnection portion 113 may be a region that is within a range of about 100-500 micrometers from an edge of the integrated device 300. The inner region 110 may include an active region (e.g., 122) and/or a plurality of die interconnects (e.g., 142).

The integrated device 300 includes a plurality of pillar interconnects 309. The plurality of pillar interconnects 309 may represent the plurality of pillar interconnects 109. The plurality of pillar interconnects 309 may include a first plurality of pillar interconnects 309a, a second plurality of pillar interconnects 309b and a third plurality of pillar interconnects 309c. The first plurality of pillar interconnects 309a may be coupled to the periphery region 110 of the integrated device 300. The first plurality of pillar interconnects 309a may be considered to be located in the periphery region 110 of the integrated device 300. In some implementations, the first plurality of pillar interconnects 309a may be located within a range of about 100-500 micrometers from an edge of the integrated device 300. The second plurality of pillar interconnects 309b and the third plurality of pillar interconnects 309c may be coupled to the inner region 112 of the integrated device 300. The second plurality of pillar interconnects 309b and the third plurality of pillar interconnects 309c may be considered to be located in the inner region 112 of the integrated device 300. In some implementations, the first plurality of pillar interconnects 309a may be configured to provide electrical paths for input/output signals. In some implementations, the third plurality of pillar interconnects 309c may be configured to provide electrical paths for input/output signals. In some implementations, the second plurality of pillar interconnects 309b may be configured to provide electrical paths for power and/or ground.

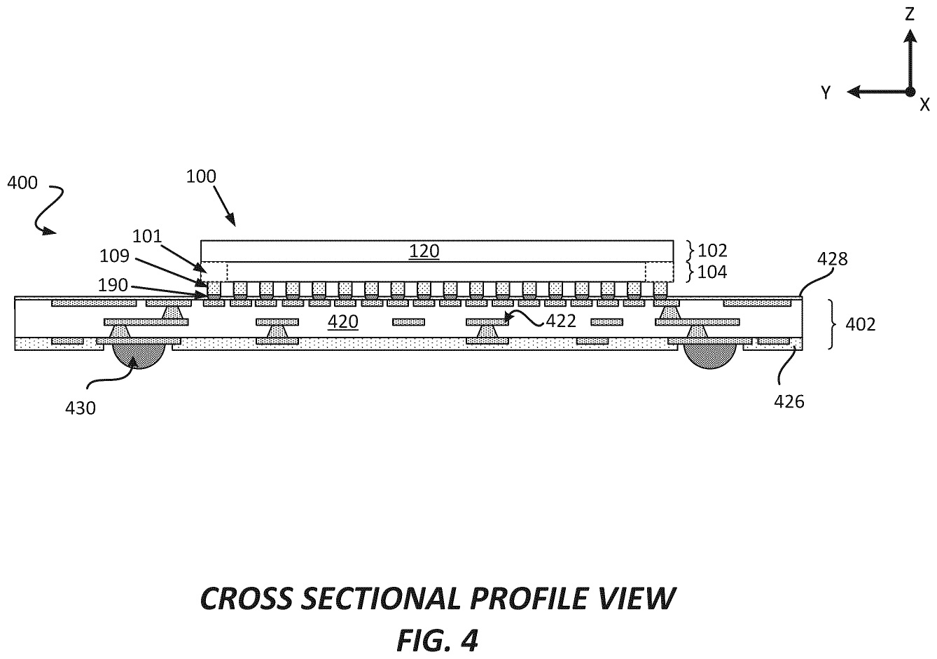

FIG. 4 illustrates an exemplary plan view of a package 400 that includes a substrate 402 and an integrated device 100. In some implementations, the package 400 may include the integrated device 200 instead of the integrated device 100. The substrate 402 may include a laminated substrate (e.g., cored substrate, coreless substrate). The substrate 402 includes at least one dielectric layer 420, a plurality of interconnects 422, a solder resist layer 426 and a solder resist layer 428. The integrated device 100 is coupled to the substrate 402 through the plurality of pillar interconnects 109 and the plurality of solder interconnects 190. For example, the integrated device 100 is coupled to the plurality of interconnects 422 of the substrate 402 through the plurality of pillar interconnects 109 and the plurality of solder interconnects 190.

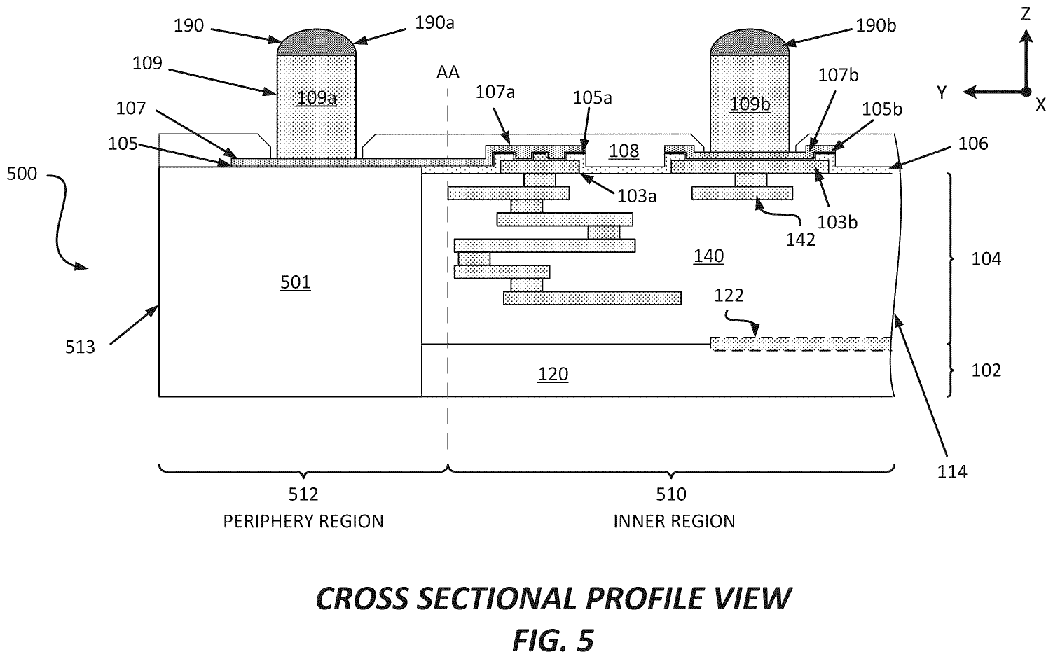

FIG. 5 illustrates a cross sectional profile view of an integrated device 500 that includes pillar interconnects, where some of the pillar interconnects are located in a periphery region of the integrated device 500. The integrated device 500 includes a die substrate portion 102, a die interconnection portion 104, a plurality of pad interconnects 103, a plurality of seed layers 105, a plurality of metallization interconnects 107, a plurality of pillar interconnects 109, a plurality of solder interconnects 190, a passivation layer 106, a passivation layer 108 and an encapsulation layer 501. The integrated device 500 includes an inner region 510 and a periphery region 512. As will be further described below, the periphery region 512 of the integrated device 500 may be configured to provide a region of the integrated device 500 that a pillar interconnect may couple with and vertically overlap with.

The die substrate portion 102 includes a die substrate 120 and an active region 122. The die substrate 120 may include silicon (Si). The active region 122 may be formed in the die substrate 120 and/or a surface of the die substrate 120. The active region 122 may include a plurality of logic cells and/or a plurality of transistors. One or more transistors may define a logic cell. Different implementations may use different types of transistors, such as a field effect transistor (FET), planar FET, finFET, and a gate all around FET. In some implementations, a front end of line (FEOL) process may be used to fabricate the plurality of cells and/or transistors in and/or over the die substrate 120. In some implementations, the die substrate portion 102 may include a plurality of through substrate vias (not shown) that extend through the die substrate 120. A back side metallization portion (not shown) may be coupled to the die substrate 120. The back side metallization portion may include a plurality of back side metallization interconnects that are coupled to the through substrate vias that extend through the die substrate 120. A portion of the die substrate 120 may be located in the inner region 510 of the integrated device 500 and another portion of the die substrate 120 may be located in the periphery region 512 of the integrated device 500. The active region 122 of the die substrate portion 102 may be located in the inner region 510 of the integrated device 500.

The die interconnection portion 104 is coupled to the die substrate portion 102. For example, the die interconnection portion 104 is coupled to the die substrate 120. The die interconnection portion 104 includes at least one dielectric layer 140 and a plurality of die interconnects 142. The plurality of die interconnects 142 may include copper (Cu). The interconnection portion 104 may be configured to be electrically coupled to the active region 122. For example, the plurality of die interconnects 142 may be configured to be electrically coupled to the active region 122. Thus, the plurality of die interconnects 142 may be configured to be electrically coupled to the plurality of logic cells and/or plurality of transistors. In some implementations, a back end of line (BEOL) process may be used to fabricate the die interconnection portion 104. The die interconnection portion 104 may be a BEOL die interconnection portion.

The encapsulation layer 501 is coupled to (i) a side surface of the die substrate portion 102 and (ii) a side surface of the die interconnection portion 104. The encapsulation layer 501 may be coupled to the at least one dielectric layer 140 of the die interconnection portion 104. The encapsulation layer 501 may be coupled to the die substrate 120. The encapsulation layer 501 may laterally surround the die substrate portion 102. The encapsulation layer 501 may laterally surround the die interconnection portion 104. The encapsulation layer 501 may be located in the periphery region 512 of the integrated device 500. The encapsulation layer 501 may be a region 513 that is free of any die interconnects (e.g., 142) and free of any active regions (e.g., free of logic cells, free of transistors). The encapsulation layer 501 may include a mold, a resin and/or an epoxy. The encapsulation layer 501 may be a means for encapsulation. The encapsulation layer 501 may be provided by using a compression and transfer molding process, a sheet molding process, or a liquid molding process. The encapsulation layer 501 may include a different material from the at least one dielectric material 140.

The at least one dielectric layer 140 may be located in the inner region 510 of the integrated device 500. The plurality of die interconnects 142 may be located in the inner region 510 of the integrated device 500. The region of the die interconnection region 140 that is located in the inner region 510 may be an inner die interconnection region 114. The inner region 510 of the integrated device 500 may be defined as a region that includes the plurality of die interconnects 142 and/or the active region 122. The periphery region 512 of the integrated device 500 may be defined as a region along the edges of the integrated device 500, that is free of the plurality of die interconnects 142 and free of the active region 122.

The plurality of pad interconnects 103 are coupled to the die interconnection portion 104. The plurality of pad interconnects 103 may be coupled to the plurality of die interconnects 142. The plurality of pad interconnects 103 may include Aluminum (Al). The plurality of pad interconnects 103 may be located in the inner region 510 of the integrated device 500.

The passivation layer 106 is coupled to the die interconnection portion 104. The passivation layer 106 may be formed and coupled to a surface of the die interconnection portion 104. The passivation layer 106 may be coupled to and touch the at least one dielectric layer 140. The passivation layer 106 may be formed and coupled to part of the plurality of pad interconnects 103. The passivation layer 106 may include silicon nitride (SiN). The passivation layer 106 may be located in the inner region 510 of the integrated device 500.

The plurality of seed layers 105 are formed and coupled to the plurality of pad interconnects 103 and the passivation layer 106. The plurality of seed layers 105 may include copper (e.g., Cu). A portion of the plurality of seed layers 105 may be located in the inner region 510 of the integrated device 500. Another portion of the plurality of seed layers 105 may be located in the periphery region 512 of the integrated device 500.

The plurality of metallization interconnects 107 may be coupled to the plurality of seed layers 105. In some implementations, the plurality of seed layers 105 may be indistinguishable from the plurality of metallization interconnects 107. In some implementations, the plurality of seed layers 105 may be considered part of the plurality of metallization interconnects 107. The plurality of metallization interconnects 107 may include copper (Cu). The plurality of metallization interconnects 107 may be coupled to the plurality of pad interconnects 103. A portion of the plurality of metallization interconnects 107 may be located in the inner region 510 of the integrated device 500. Another portion of the plurality of metallization interconnects 107 may be located in the periphery region 512 of the integrated device 500. The plurality of metallization interconnects 107 may include a plurality of redistribution interconnects.

The passivation layer 108 is coupled the passivation layer 106 and the plurality of metallization interconnects 107. The passivation layer 108 may include polyimide. The plurality of pillar interconnects 109 may be coupled to the plurality of metallization interconnects 107. Some of the pillar interconnects from the plurality of pillar interconnects 109 may be located in the inner region 510 of the integrated device 500. Other pillar interconnects from the plurality of pillar interconnects 109 may be located in the periphery region 512 of the integrated device 500. The plurality of pillar interconnects 109 may include copper (Cu). The plurality of solder interconnects 190 may be coupled to the plurality of pillar interconnects 109.

In some implementations, a back end of line (BEOL) process may be used to fabricate the die interconnection portion 104, the passivation layer 106 and/or the plurality of pad interconnects 103.

The plurality of pad interconnects 103 includes a pad interconnect 103a (e.g., first pad interconnect) and a pad interconnect 103b (e.g., second pad interconnect). The plurality of seed layer 105 includes a seed layer 105a and a seed layer 105b. The plurality of metallization interconnects 107 may include a metallization interconnect 107a (e.g., first metallization interconnect) and a metallization interconnect 107b (e.g., second metallization interconnect). The plurality of pillar interconnects 109 includes a pillar interconnect 109a (e.g., first pillar interconnect) and a pillar interconnect 109b (e.g., second pillar interconnect).

The pad interconnect 103a and the pad interconnect 103b are located in the inner region 510 of the integrated device 500. The pad interconnect 103a and the pad interconnect 103b vertically overlap with the inner die interconnection portion 114. The pad interconnect 103a is coupled to a first die interconnect from the plurality of die interconnects 142. The pad interconnect 103b is coupled to a second die interconnect from the plurality of die interconnects 142.

The seed layer 105a is coupled to the pad interconnect 103a. The metallization interconnect 107a is coupled to the seed layer 105a. The seed layer 105a may be considered part of the metallization interconnect 107a. Thus, the metallization interconnect 107a may be considered to be coupled to the pad interconnect 103a. The metallization interconnect 107a is coupled to the pillar interconnect 109a. The solder interconnect 190a is coupled to the pillar interconnect 109a.

The seed layer 105b is coupled to the pad interconnect 103b. The metallization interconnect 107b is coupled to the seed layer 105b. The seed layer 105b may be considered part of the metallization interconnect 107b. Thus, the metallization interconnect 107b may be considered to be coupled to the pad interconnect 103b. The metallization interconnect 107b is coupled to the pillar interconnect 109b. The solder interconnect 190b is coupled to the pillar interconnect 109b.

The pillar interconnect 109a and the solder interconnect 190a may vertically overlap with the periphery region 512 of the integrated device 500. A portion of the seed layer 105a and a portion of the metallization interconnect 107a may be located in the periphery region 512 of the integrated device 500. In some implementations, the pillar interconnect 109a and the solder interconnect 190a may be considered to be located in the periphery region 512 of the integrated device 500. The pillar interconnect 109a and the solder interconnect 190a may not vertically overlap with the plurality of die interconnects 142 of the die interconnection portion 104. The pillar interconnect 109a and the solder interconnect 190a may not vertically overlap with the active region 122 of the die substrate portion 102. The pillar interconnect 109a and the solder interconnect 190a vertically overlap with the encapsulation layer 501.

Another portion of the seed layer 105a and another portion of the metallization interconnect 107a may be located in the inner region 510 of the integrated device 500. The seed layer 105b, the metallization interconnect 107b, the pillar interconnect 109b and the solder interconnect 190b may be considered to be located in the inner region 510 of the integrated device 500. The pillar interconnect 109b and the solder interconnect 190b may vertically overlap with the plurality of die interconnects 142. In some implementations, the pillar interconnect 109b and the solder interconnect 190b may vertically overlap with the active region 122.

FIG. 5 illustrates an integrated device that extends a region to be used for additional electrical paths. In particular, the integrated device 500 provides metallization interconnects in a periphery region 512 that is free of the plurality of die interconnects and free of the active region 122, which allows more electrical paths to and/or from the integrated device, which can lead to improved performance of the integrated device 500. In addition, the additional space means that the pitch between pillar interconnects do not need to be as small, which can provide improved yields during the manufacturing of the integrated device 500. This can result in a lower cost for the manufacturing of the integrated device 500.

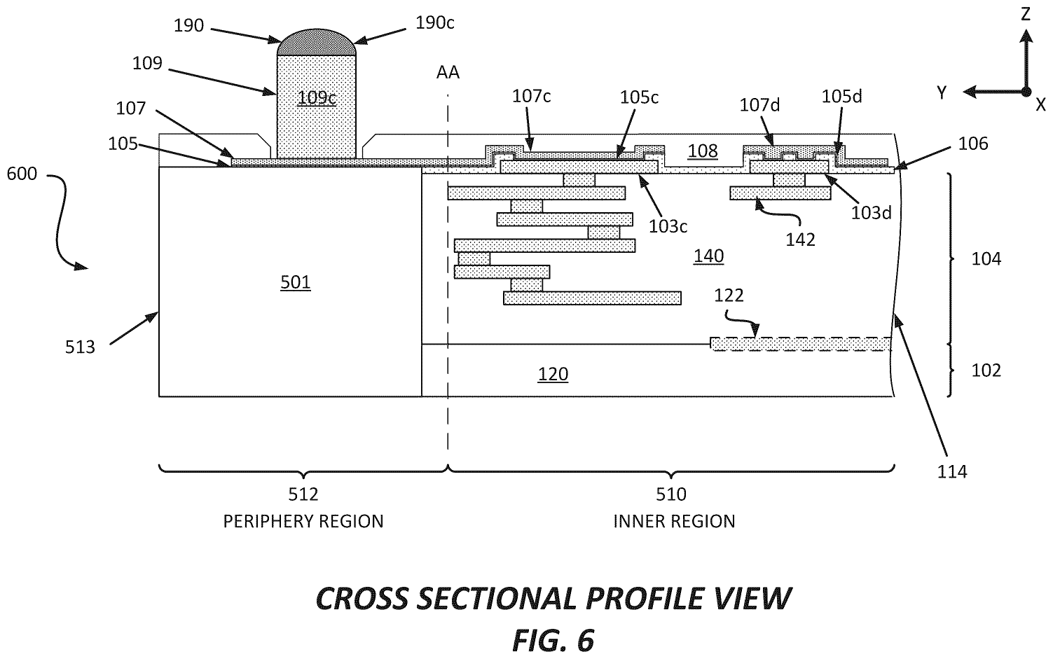

FIG. 6 illustrates a cross sectional profile view of an integrated device 600 that includes pillar interconnects, where some of the pillar interconnects are located in a periphery region of the integrated device 600. The integrated device 600 is similar to the integrated device 500 of FIG. 5, and includes similar components that are arranged in a similar manner as described for the integrated device 500. The integrated device 600 illustrates how pillar interconnects may be redistributed to a different region of an integrated device. The integrated device 200 includes a die substrate portion 102, a die interconnection portion 104, a plurality of pad interconnects 103, a plurality of seed layers 105, a plurality of metallization interconnects 107, a plurality of pillar interconnects 109, a plurality of solder interconnects 190, a passivation layer 106, a passivation layer 108 and the encapsulation layer 501. The integrated device 100 includes an inner region 110 and a periphery region 112.

The plurality of pad interconnects 103 includes a pad interconnect 103c (e.g., first pad interconnect) and a pad interconnect 103d (e.g., second pad interconnect). The plurality of seed layer 105 includes a seed layer 105c and a seed layer 105d. The plurality of metallization interconnects 107 may include a metallization interconnect 107c (e.g., first metallization interconnect) and a metallization interconnect 107d (e.g., second metallization interconnect). The plurality of pillar interconnects 109 includes a pillar interconnect 109c (e.g., first pillar interconnect).

FIG. 6 illustrates how metallization interconnects may be extended in the periphery region 512 to redistribute the location of the pillar interconnects and provide additional space for more pillar interconnects. Under a different configuration, the pillar interconnect 109c may be located in the inner region 110, and the pillar interconnect 109c may vertically overlap with the pad interconnect 103c. However, in the configuration shown of FIG. 6, the pillar interconnect 109c does not vertically overlap with the pad interconnect 103c. The pillar interconnect 109c is coupled to the pad interconnect 103c through the metallization interconnect 107c.

In some implementations, an integrated device (e.g., 500, 600) may include one or more alignment markers. These alignment markers may be alignment interconnects. These alignment markers may help a device, a machine and/or a system for singulating a wafer into integrated devices. Such a device, a machine and/or a system may use the alignment markers so that the laser and/or saw that singulates the wafer, cuts in the proper regions of the wafer. For example, the device, the machine and/or the system may singulate wafers between two alignment markers. These alignment markers may have a specific shape that indicate that they are alignment markers. These alignment markers may be located in a region that is planar to the plurality of metallization interconnects 107. In some implementations, the boundary AA between the periphery region and the inner region may be defined by these alignment markers. For example, the vertical boundary (e.g., boundary wall) between the periphery region and the inner region of an integrated device may be defined by one or more alignment markers. Thus, one or more alignment markers may be located on or about the boundary AA between the periphery region 512 and the inner region 510 of an integrated device (e.g., 500, 600). However, one or more alignment markers may not be located on the boundary AA. In some implementations, the plurality of pillar interconnects 109 may be located on both sides (e.g., to the left and to the right) of these alignment markers. In some implementations, the periphery region 512 of the integrated device (e.g., 500, 600) may be defined as a region between a particular edge of the integrated device and a particular alignment marker that is nearest to the particular edge.

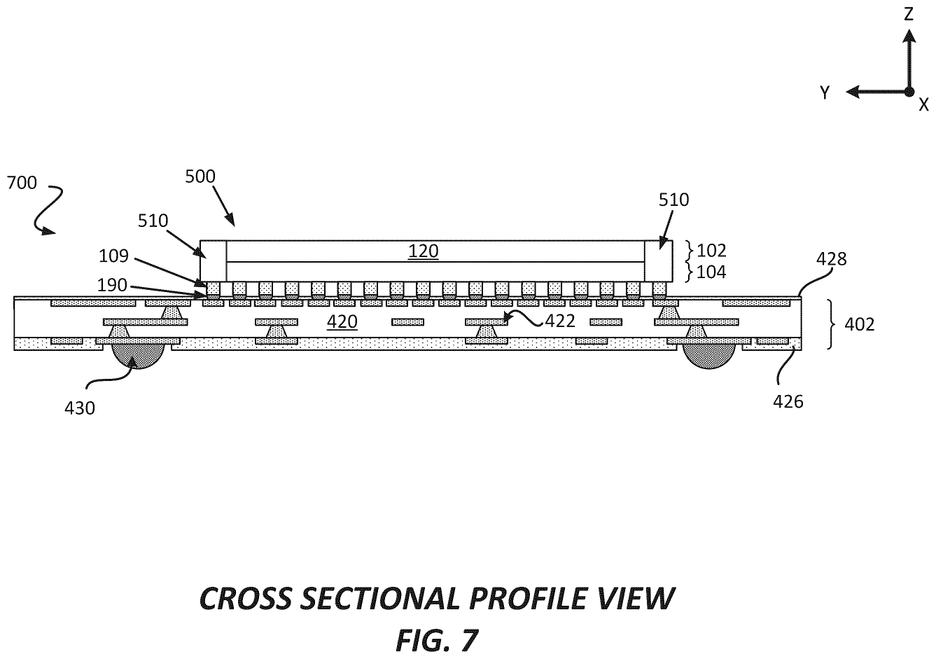

FIG. 7 illustrates an exemplary plan view of a package 700 that includes a substrate 402 and an integrated device 500. In some implementations, the package 700 may include the integrated device 600 instead of the integrated device 500. The substrate 402 may include a laminated substrate (e.g., cored substrate, coreless substrate). The substrate 402 includes at least one dielectric layer 420, a plurality of interconnects 422, a solder resist layer 426 and a solder resist layer 428. The integrated device 500 is coupled to the substrate 402 through the plurality of pillar interconnects 109 and the plurality of solder interconnects 190. For example, the integrated device 500 is coupled to the plurality of interconnects 422 of the substrate 402 through the plurality of pillar interconnects 109 and the plurality of solder interconnects 190. It is noted that a package may also include several integrated devices (e.g., 100, 200, 500, 600) and is not limited to a single integrated.

An integrated device (e.g., 100, 200, 500, 600) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

Having described an integrated device with pillar shell interconnects and inner solder interconnects, a method for fabricating an integrated device will now be described below.

### Exemplary Sequence for Fabricating an Integrated Device

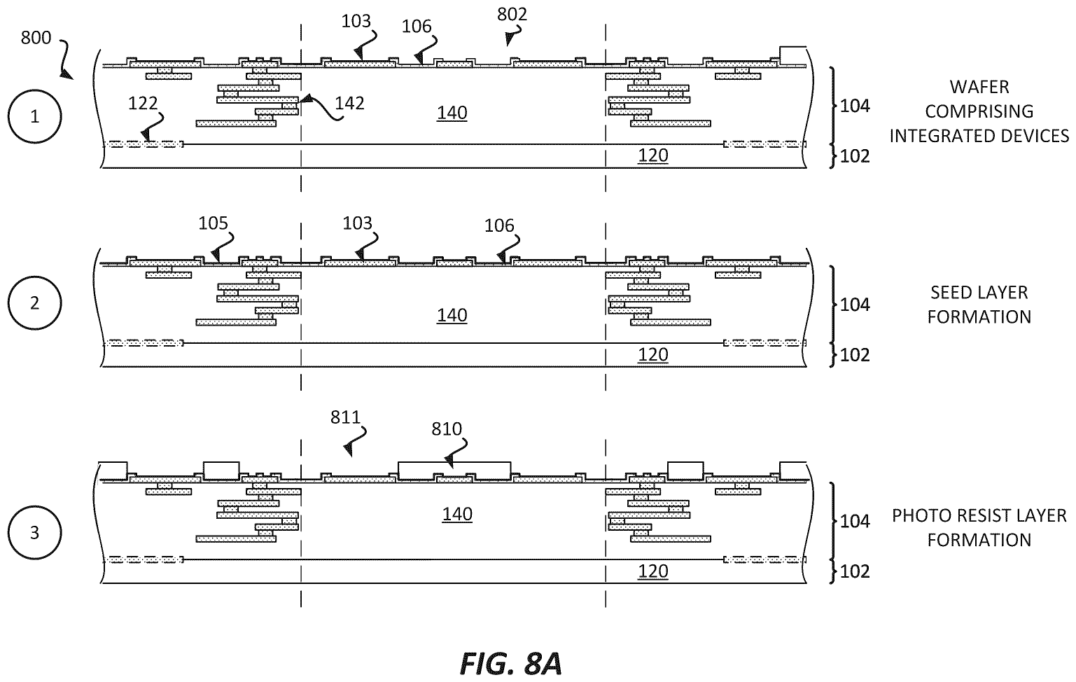

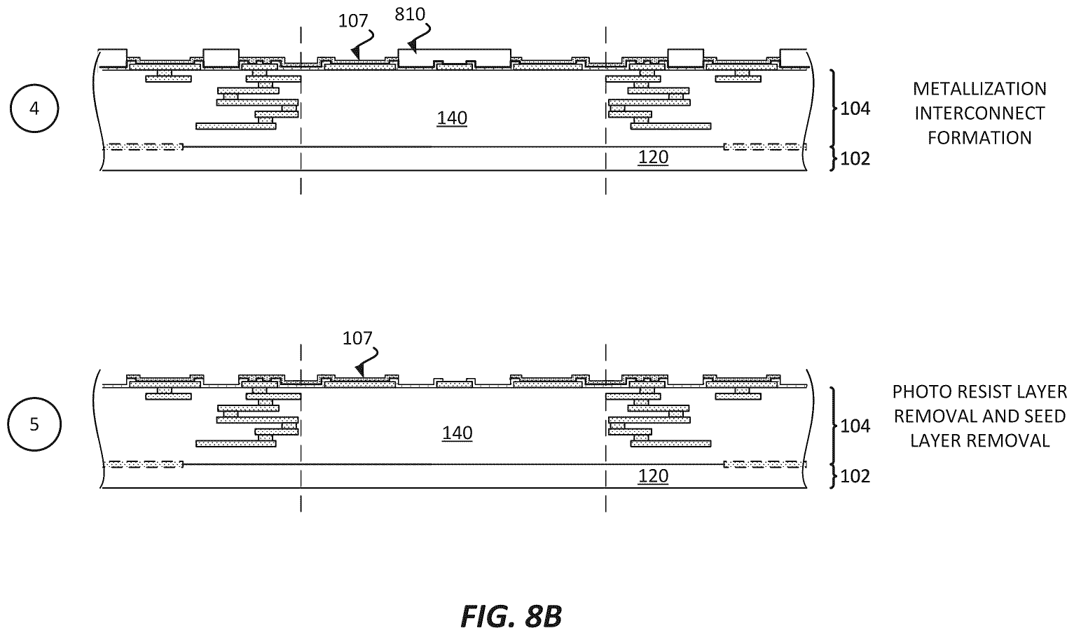

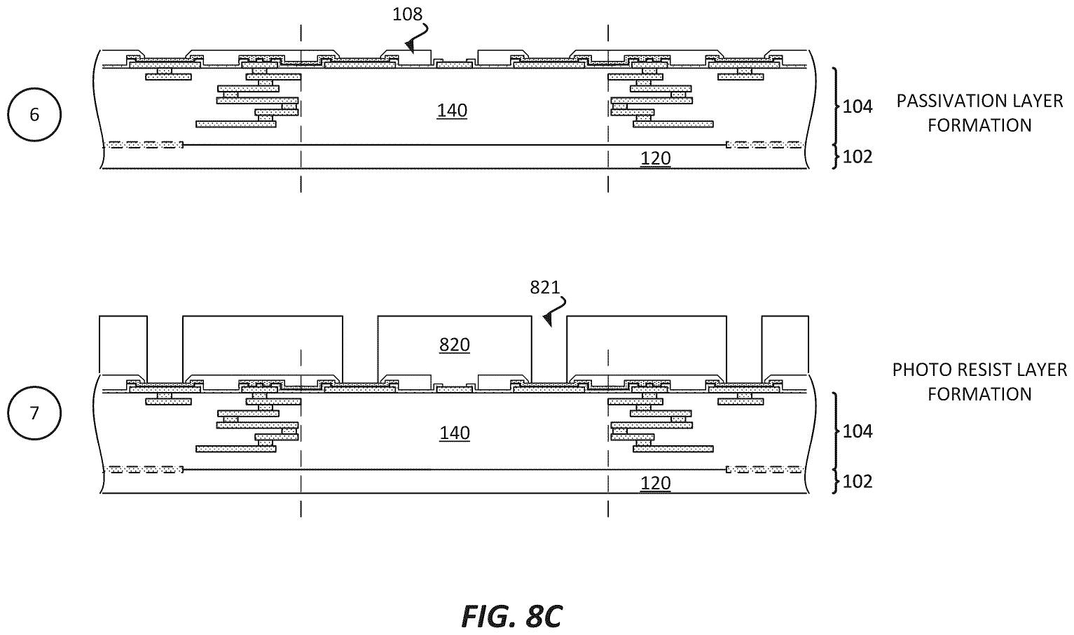

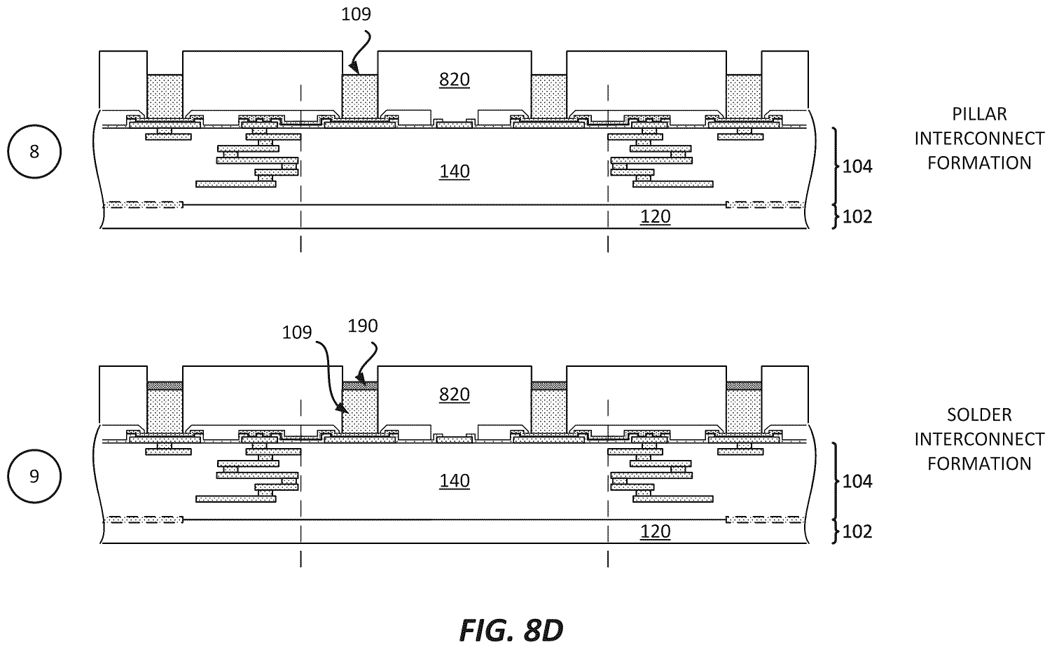

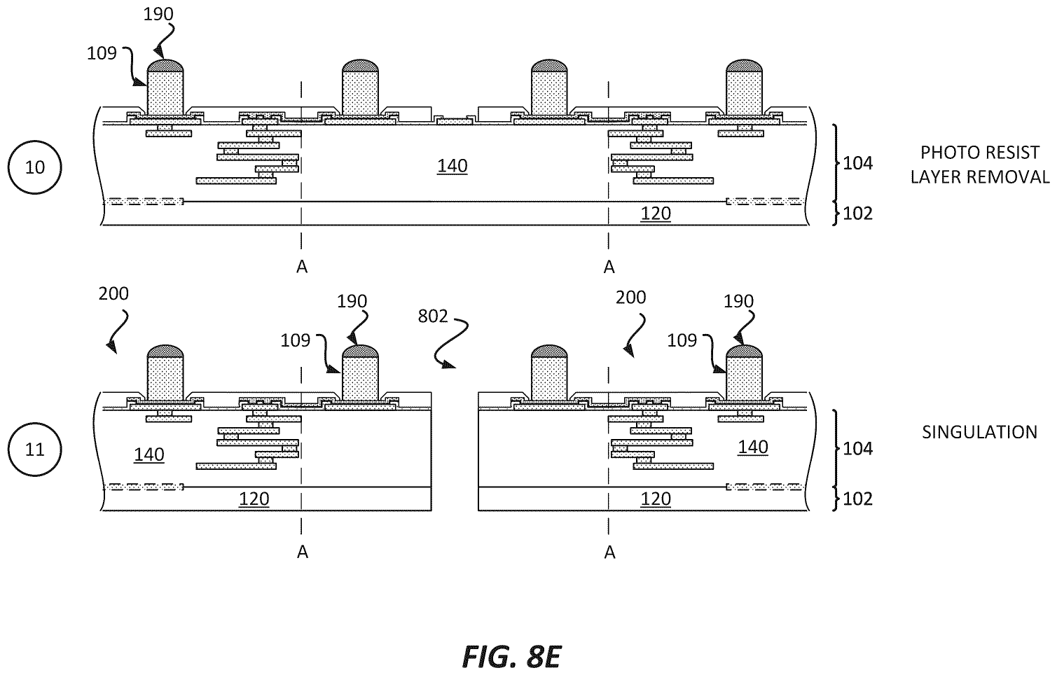

In some implementations, fabricating an integrated device includes several processes. FIGS. 8A-8E illustrate an exemplary sequence for providing or fabricating an integrated device comprising a pillar shell interconnect and an inner solder interconnect. In some implementations, the sequence of FIGS. 8A-8E may be used to provide or fabricate the integrated device 200. However, the process of FIGS. 8A-8E may be used to fabricate any of the integrated devices described in the disclosure.

It should be noted that the sequence of FIGS. 8A-8E may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 8A, illustrates a state after a wafer 800 is provided. The wafer 800 may include a die substrate portion 102, a die interconnection portion 104, a die substrate 120, the active region 122, at least one dielectric layer 140, a plurality of die interconnects 142, a plurality of pad interconnects 103, a passivation layer 106. The wafer 800 may include uncut integrated devices. The wafer 800 includes scribe regions 802. The scribe regions 802 are regions where the wafer 800 may be cut to singulate the wafer 800 into individual integrated devices. In some implementations, the edge(s) of a scribe regions 802 may define a boundary between the periphery region (e.g., 112) and the inner region (e.g., 110) of an integrated device. In some implementations, the scribe regions 802 may be identified and/or define by alignment markers (e.g., alignment interconnects). These alignment markers help ensure that the proper portion of the wafer is cut. In some implementations, these alignment markers may be located in a region that is planar to the plurality of metallization interconnects 107. In some implementations, these alignment markers may be located in a region that is planar to the plurality of pad interconnects 103. In some implementations, these alignment markers may be located in the at least one dielectric layer 140. A FEOL process and a BEOL process may be used to fabricate the wafer 800 that includes a plurality of uncut integrated devices.

Stage 2 illustrates a state after a seed layer 105 are formed over the wafer 800, The seed layer 105 may be formed over the passivation layer 106 and the plurality of pad interconnects 103. The seed layer 105 may include copper (Cu). A sputtering process may be used to form the seed layer 105.

Stage 3 illustrates a state after a photo resist layer 810 is formed over the wafer 800. For example, the photo resist layer 810 may be formed over the seed layer 105. The photo resist layer 810 may be patterned to include a plurality of openings 811 in the photo resist layer 810. The photo resist layer 810 may be coated over the wafer 800. A photolithography process may be used to form and define the pattern of the photo resist layer 810. For example, an exposure process and development process may be used to form the plurality of openings 811 in the photo resist layer 810. The plurality of openings 811 may be located over the plurality of pads 103.

Stage 4, as shown in FIG. 8B illustrates a state after the plurality of metallization interconnects 107 are formed and coupled to the seed layer 105. The plurality of metallization interconnects 107 may be formed and coupled to the plurality of pad interconnects 103 through the seed layer 105. A plating process may be used to form the plurality of metallization interconnects 107. The plurality of metallization interconnects 107 may be formed in the plurality of openings 811 of the photo resist layer 810.

Stage 5 illustrates a state after the photo resist layer 810 is removed. Stage 5 may also illustrate a state after portions of the seed layer 105 are removed. The remaining seed layer 105 may be considered part of the plurality of metallization interconnects 107. A strip process may be used to remove the photo resist layer 810. An etching process may be used to selectively remove portions of the seed layer 105.

Stage 6, as shown in FIG. 8C, illustrates a state after a passivation layer 108. The passivation layer 108 may be formed over the wafer 800. For example, the passivation layer 108 may be formed over the passivation layer 106 and portions of the plurality of metallization interconnects 107. A deposition process, a lamination process, an exposure process and/or development process may be used to form the passivation layer 108.

Stage 7 illustrates a state after a photo resist layer 820 is formed over the wafer 800. For example, the photo resist layer 820 may be formed over the passivation layer 108. The photo resist layer 820 may be patterned to include a plurality of openings 821 in the photo resist layer 820. The photo resist layer 820 may be coated over the wafer 800. A photolithography process may be used to form and define the pattern of the photo resist layer 820. For example, an exposure process and development process may be used to form the plurality of openings 821 in the photo resist layer 820. The plurality of openings 821 may be located over the plurality of pads 103 and/or portions of the plurality of metallization interconnects 107.

Stage 8, as shown in FIG. 8D illustrates a state after the plurality of pillar interconnects 109 are formed and coupled to the plurality of metallization interconnects 107. A plating process may be used to form the plurality of pillar interconnects 109. The plurality of pillar interconnects 109 may be formed in the plurality of openings 821 of the photo resist layer 820.

Stage 9 illustrates a state after the plurality of solder interconnects 190 are formed and coupled to the plurality of pillar interconnects 109. The plurality of solder interconnects 190 may be formed through the plurality of openings 821 of the photo resist layer 820. A pasting process may be used to form the plurality of solder interconnects 190.

Stage 10, as shown in FIG. 8E, illustrates a state after the photo resist layer 820 is removed. A strip process may be used to remove the photo resist layer 820. A solder reflow process may be performed, which couples the plurality of solder interconnects 190 to the plurality of pillar interconnects 109.

Stage 11 illustrates a state after singulation of the wafer 800 individual integrated devices. The wafer 800 may be cut through the scribe region 802. A mechanical process (e.g., saw process) may be used to singulate the wafer 800. As mentioned above, in some implementations, the scribe region 802 may be identified and/or define by alignment markers (e.g., alignment interconnects). These alignment markers help ensure that the proper portion of the wafer is cut during singulation. In some implementations, one or more alignment markers may be located on or about the scribe line A. In some implementations, these alignment markers may be located in a region that is planar to the plurality of metallization interconnects 107. In some implementations, these alignment markers may be located in a region that is planar to the plurality of pad interconnects 103. In some implementations, these alignment markers may be located in the at least one dielectric layer 140. After singulation, the integrated device 200 may be fabricated, where the integrated device 200 includes a pillar interconnect that is located in a periphery region of the integrated device 200 that is free of die interconnects and free of an active region. However, in some implementations, the periphery region 112 may include a die interconnect and/or transistors.

### Exemplary Flow Diagram of a Method for Fabricating an Integrated Device

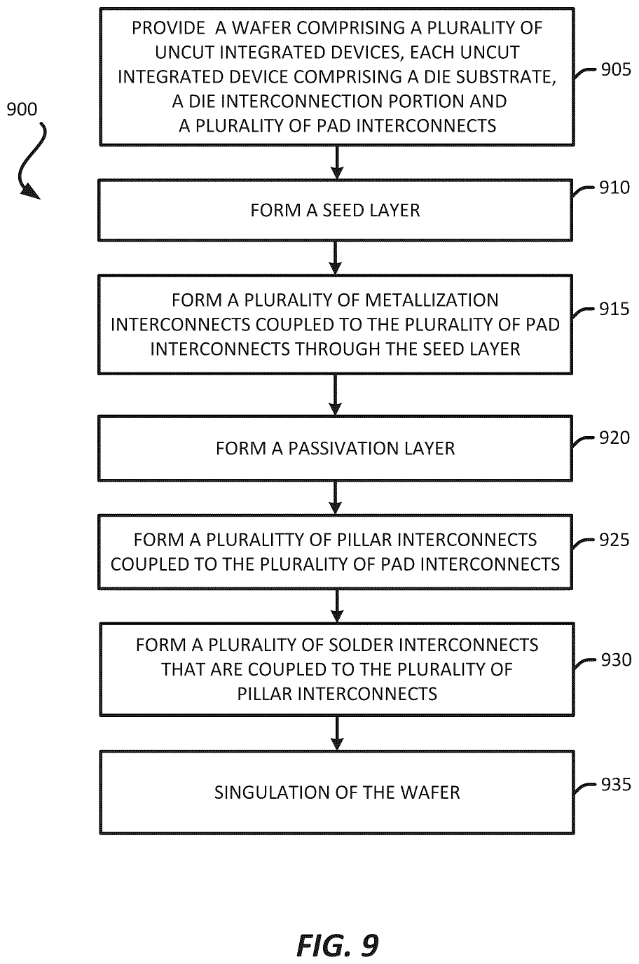

In some implementations, fabricating an integrated device includes several processes. FIG. 9 illustrates an exemplary flow diagram of a method 900 for providing or fabricating an integrated device. In some implementations, the method 900 of FIG. 9 may be used to provide or fabricate the integrated device 200 of FIG. 2 described in the disclosure. However, the method 900 may be used to provide or fabricate any of the integrated devices described in the disclosure.

It should be noted that the method 900 of FIG. 9 may combine one or more processes in order to simplify and/or clarify the method for providing or fabricating an integrated device. In some implementations, the order of the processes may be changed or modified.

The method provides (at 905) a wafer that includes uncut integrated devices. Stage 1 of FIG. 8A, illustrates and describes an example of a state after a wafer 800 is provided. The wafer 800 may include a die substrate portion 102, a die interconnection portion 104, a die substrate 120, the active region 122, at least one dielectric layer 140, a plurality of die interconnects 142, a plurality of pad interconnects 103, a passivation layer 106. The wafer 800 may include uncut integrated devices. The wafer 800 includes scribe regions 802. The scribe regions 802 are regions where the wafer 800 may be cut to singulate the wafer 800 into individual integrated devices. In some implementations, the edge(s) of a scribe regions 802 may define a boundary between the periphery region (e.g., 112) and the inner region (e.g., 110) of an integrated device. In some implementations, the scribe regions 802 may be identified and/or define by alignment markers (e.g., alignment interconnects). These alignment markers help ensure that the proper portion of the wafer is cut. In some implementations, these alignment markers may be located in a region that is planar to the plurality of pad interconnects 103. In some implementations, these alignment markers may be located in the at least one dielectric layer 140. A FEOL process and a BEOL process may be used to fabricate the wafer 800 that includes a plurality of uncut integrated devices.

The method forms (at 910) a seed layer. Stage 2 of FIG. 8A, illustrates and describes an example of a state after a seed layer 105 are formed over the wafer 800, The seed layer 105 may be formed over the passivation layer 106 and the plurality of pad interconnects 103. The seed layer 105 may include copper (Cu). A sputtering process may be used to form the seed layer 105.

The method forms (at 915) a plurality of metallization interconnects that are coupled to the plurality of pad interconnects through the seed layer. Stages 3 through 5 of FIGS. 8A-8B illustrate and describe an example of forming a plurality of metallization interconnects.

Stage 3 of FIG. 8A, illustrates and describes an example of a state after a photo resist layer 810 is formed over the wafer 800. For example, the photo resist layer 810 may be formed over the seed layer 105. The photo resist layer 810 may be patterned to include a plurality of openings 811 in the photo resist layer 810. The photo resist layer 810 may be coated over the wafer 800. A photolithography process may be used to form and define the pattern of the photo resist layer 810. For example, an exposure process and development process may be used to form the plurality of openings 811 in the photo resist layer 810. The plurality of openings 811 may be located over the plurality of pads 103.

Stage 4 of FIG. 8B, illustrates and describes an example of a state after the plurality of metallization interconnects 107 are formed and coupled to the seed layer 105. The plurality of metallization interconnects 107 may be formed and coupled to the plurality of pad interconnects 103 through the seed layer 105. A plating process may be used to form the plurality of metallization interconnects 107. The plurality of metallization interconnects 107 may be formed in the plurality of openings 811 of the photo resist layer 810.

Stage 5 of FIG. 8B, illustrates and describes an example of a state after the photo resist layer 810 is removed. Stage 5 may also illustrate a state after portions of the seed layer 105 are removed. The remaining seed layer 105 may be considered part of the plurality of metallization interconnects 107. A strip process may be used to remove the photo resist layer 810. An etching process may be used to selectively remove portions of the seed layer 105.

The method forms (at 920) a passivation layer. Stage 6 of FIG. 8C, illustrates and describes an example of a state after a passivation layer 108. The passivation layer 108 may be formed over the wafer 800. For example, the passivation layer 108 may be formed over the passivation layer 106 and portions of the plurality of metallization interconnects 107. A deposition process, a lamination process, an exposure process and/or development process may be used to form the passivation layer 108.

The method forms (at 925) a plurality of pillar interconnects that are coupled to the plurality of metallization interconnects. Stages 7 through 8 of FIGS. 8C-8D illustrate and describe an example of forming a plurality of pillar interconnects.

Stage 7 of FIG. 8C, illustrates and describes an example of a state after a photo resist layer 820 is formed over the wafer 800. For example, the photo resist layer 820 may be formed over the passivation layer 108. The photo resist layer 820 may be patterned to include a plurality of openings 821 in the photo resist layer 820. The photo resist layer 820 may be coated over the wafer 800. A photolithography process may be used to form and define the pattern of the photo resist layer 820. For example, an exposure process and development process may be used to form the plurality of openings 821 in the photo resist layer 820. The plurality of openings 821 may be located over the plurality of pads 103 and/or portions of the plurality of metallization interconnects 107.

Stage 8 of FIG. 8D, illustrates and describes an example of a state after the plurality of pillar interconnects 109 are formed and coupled to the plurality of metallization interconnects 107. A plating process may be used to form the plurality of pillar interconnects 109. The plurality of pillar interconnects 109 may be formed in the plurality of openings 821 of the photo resist layer 820.

The method forms and couples (at 930) a plurality of solder interconnects to the plurality of pillar interconnects. Stage 9 of FIG. 8D, illustrates and describes an example of a state after the plurality of solder interconnects 190 are formed and coupled to the plurality of pillar interconnects 109. The plurality of solder interconnects 190 may be formed through the plurality of openings 821 of the photo resist layer 820. A pasting process may be used to form the plurality of solder interconnects 190. Stage 10 of FIG. 8E, illustrates and describes an example of a state after the photo resist layer 820 is removed. A strip process may be used to remove the photo resist layer 820. A solder reflow process may be performed, which couples the plurality of solder interconnects 190 to the plurality of pillar interconnects 109.

The method singulates (at 935) the wafer to form a plurality of integrated devices. Stage 11 of FIG. 8E, illustrates and describes an example of a state after singulation of the wafer 800 into individual integrated devices. The wafer 800 may be cut through the scribe region 802. As mentioned above, in some implementations, the scribe region 802 may be identified and/or define by alignment markers (e.g., alignment interconnects). These alignment markers help ensure that the proper portion of the wafer is cut during singulation. In some implementations, these alignment markers may be located in a region that is planar to the plurality of pad interconnects 103. In some implementations, these alignment markers may be located in the at least one dielectric layer 140. A mechanical process (e.g., saw process) may be used to singulate the wafer 800. After singulation, the integrated device 200 may be fabricated, where the integrated device 200 includes a pillar interconnect that is located in a periphery region of the integrated device 200 that is free of die interconnects and free of an active region. However, in some implementations, the periphery region 112 may include a die interconnect and/or transistors.

### Exemplary Sequence for Fabricating an Integrated Device

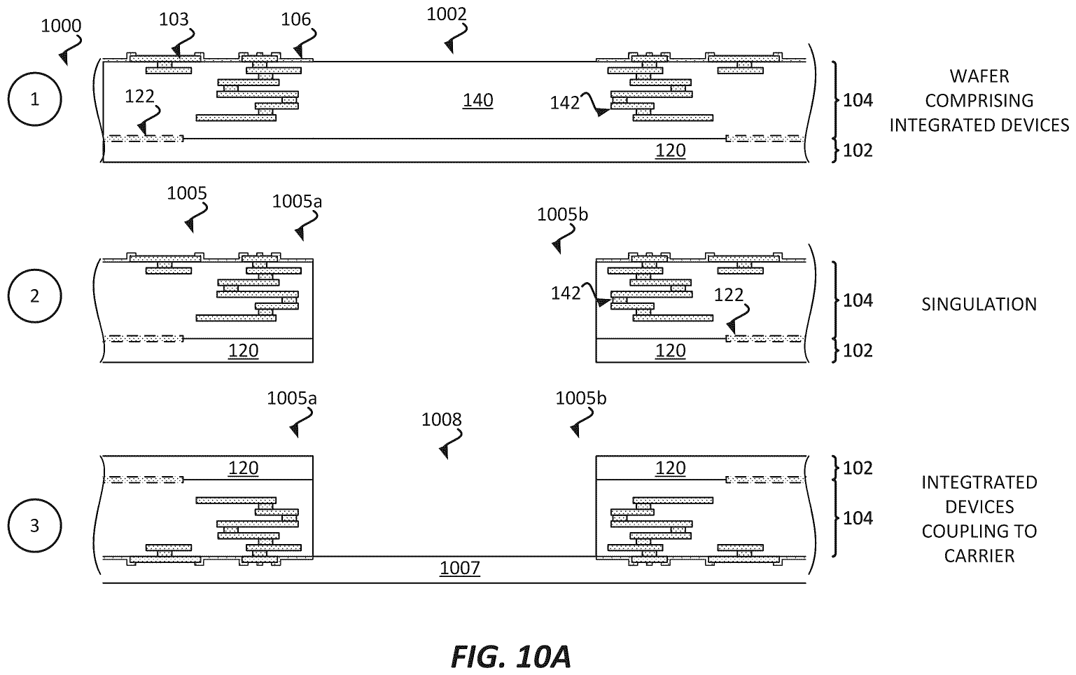

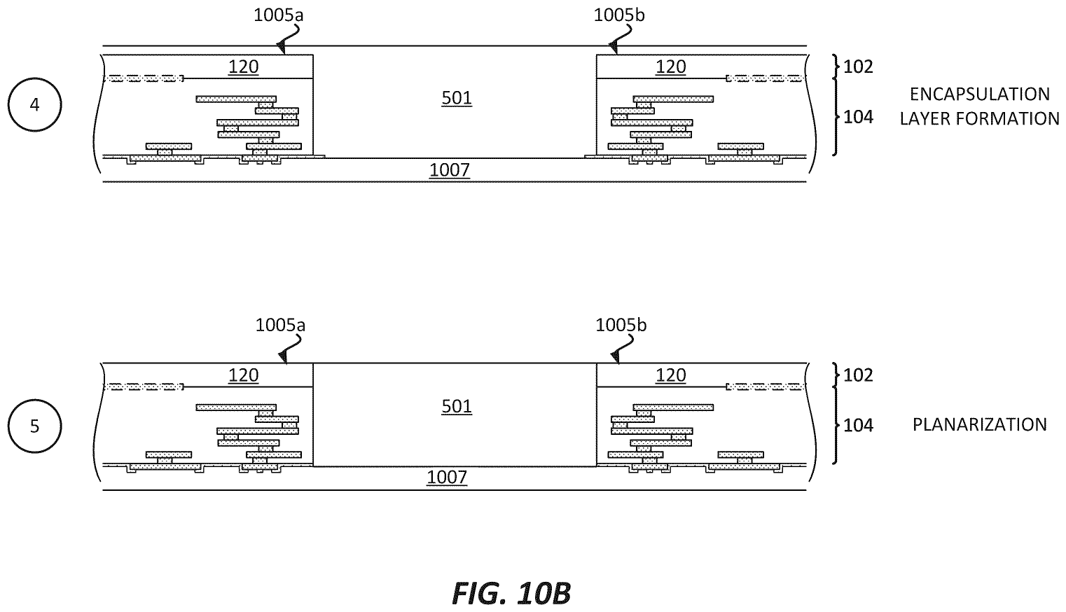

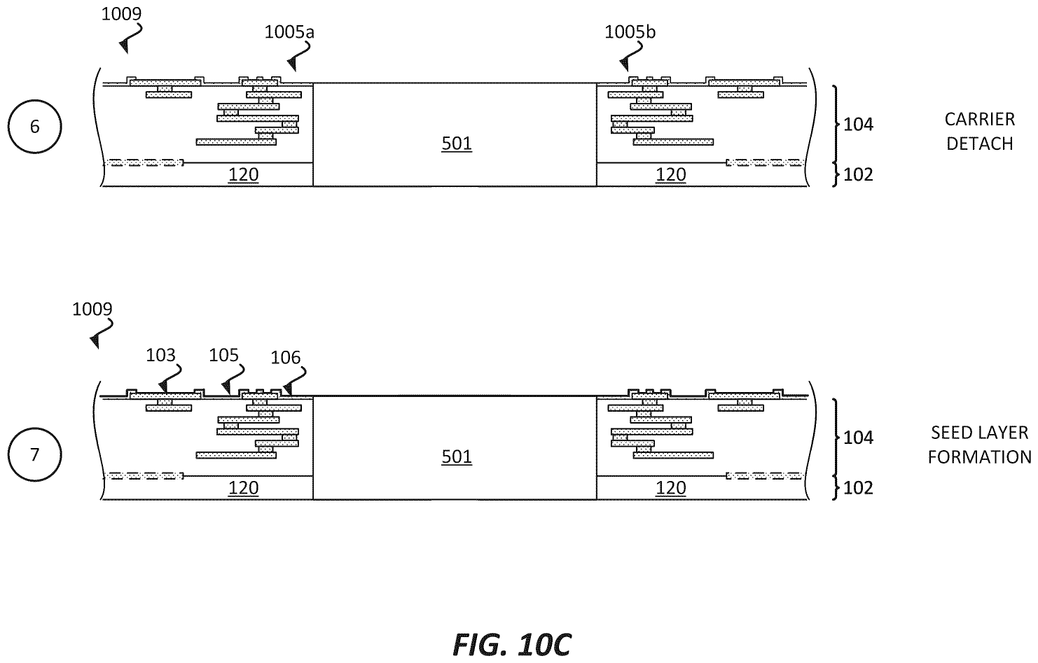

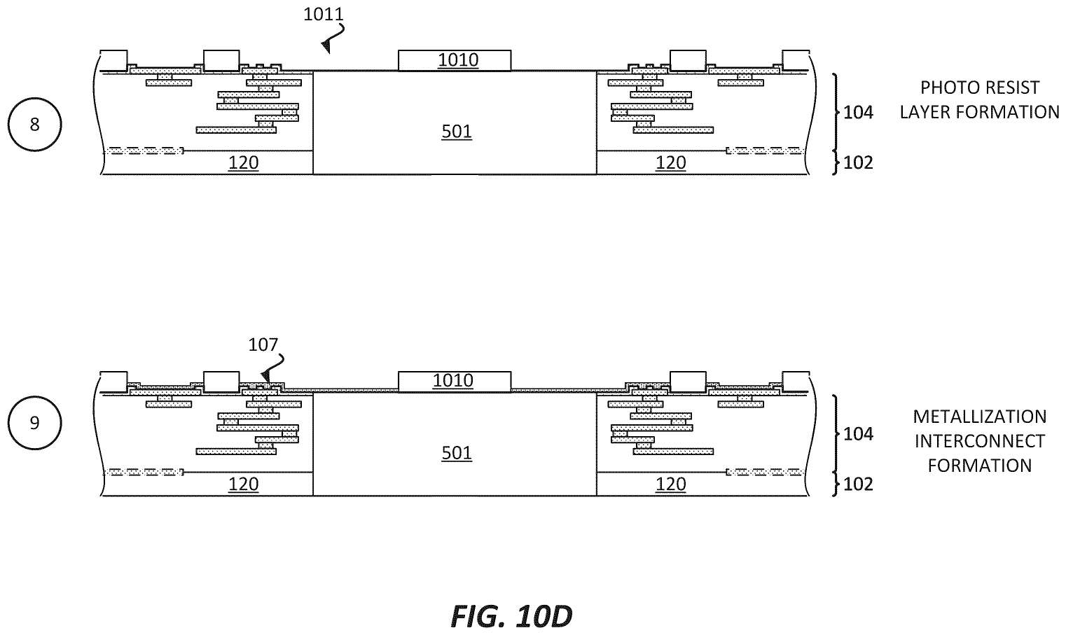

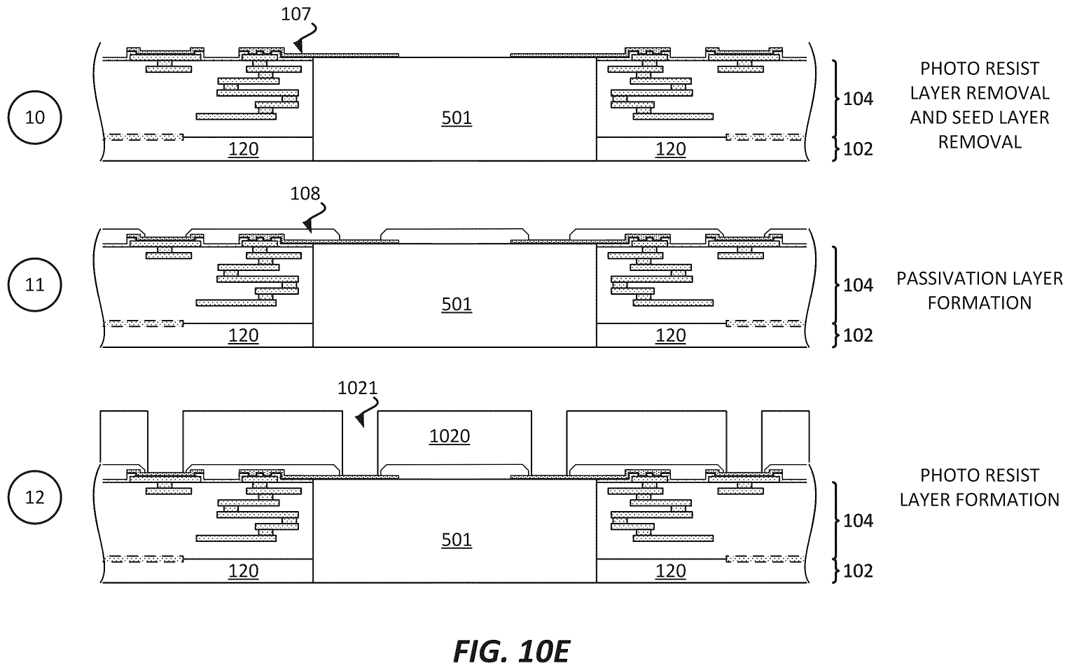

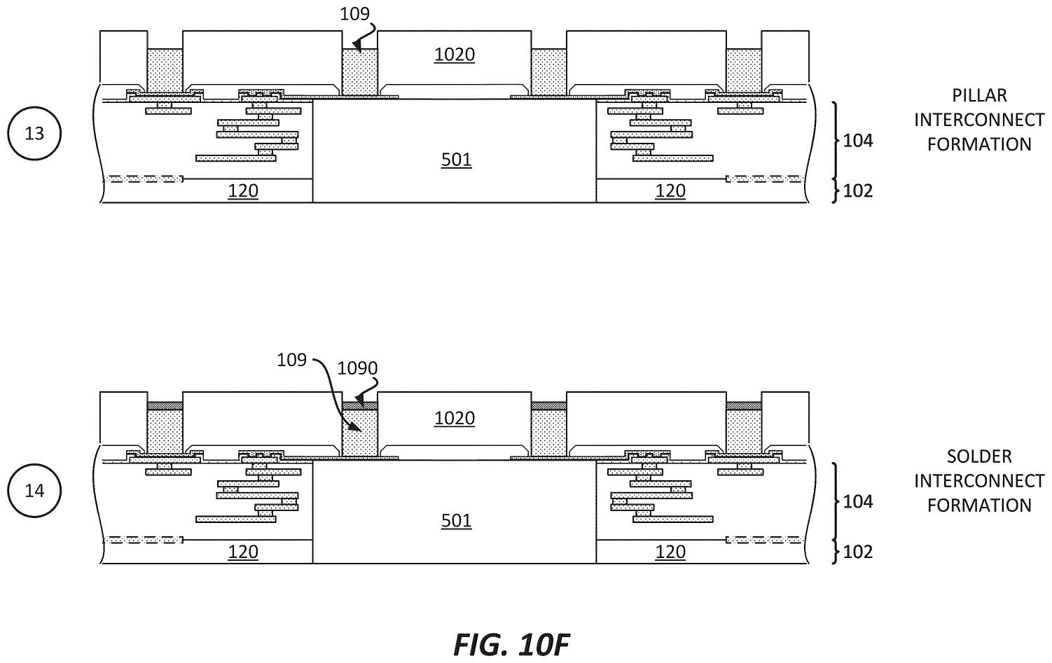

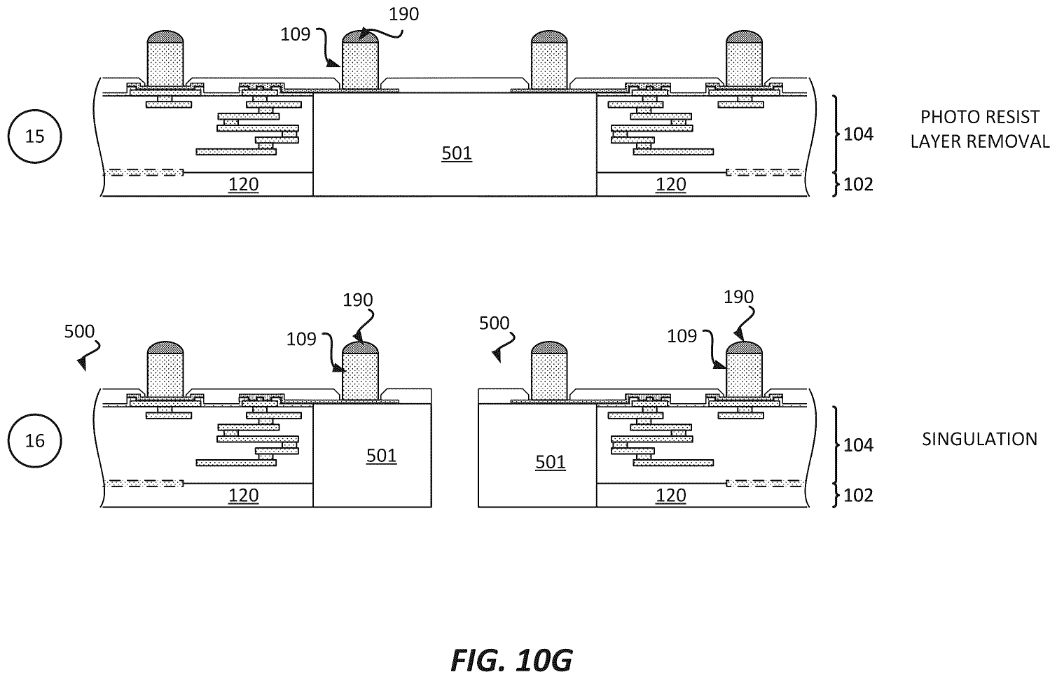

In some implementations, fabricating an integrated device includes several processes. FIGS. 10A-10G illustrate an exemplary sequence for providing or fabricating an integrated device comprising a pillar shell interconnect and an inner solder interconnect. In some implementations, the sequence of FIGS. 10A-10G may be used to provide or fabricate the integrated device 500. However, the process of FIGS. 10A-10G may be used to fabricate any of the integrated devices described in the disclosure.

It should be noted that the sequence of FIGS. 10A-10G may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 10A, illustrates a state after a wafer 1000 is provided. The wafer 1000 may include a die substrate portion 102, a die interconnection portion 104, a die substrate 120, the active region 122, at least one dielectric layer 140, a plurality of die interconnects 142, a plurality of pad interconnects 103, a passivation layer 106. The wafer 1000 may include uncut integrated devices. The wafer 1000 includes scribe regions 1002. The scribe regions 1002 are regions where the wafer 1000 may be cut to singulate the wafer 1000 into individual integrated devices. A FEOL process and a BEOL process may be used to fabricate the wafer 1000 that includes a plurality of uncut integrated devices.

Stage 2 illustrates a state after the wafer 1000 is cut and/or singulate to form a plurality of integrated devices 1005 (e.g., semiconductor dies). The plurality of integrated devices 1005 may include an integrated device 1005a and an integrated device 1005b. Each integrated device may include a die substrate portion 102, a die interconnection portion 104, a plurality of pad interconnects 103 and a passivation layer 106. The wafer 1000 may be cut along the scribe regions 1002 of the wafer 1000. A mechanical process (e.g., saw process) may be used to singulate the wafer 1000.

Stage 3 illustrates a state after the plurality of integrated devices 1005 are placed and coupled to a carrier 1007. An adhesive (not shown) may be used to place and couple the plurality of integrated devices 1005 to the carrier 1007. There may be a space 1008 between the integrated devices. For example, there is a space 1008 between the integrated device 1005a and the integrated device 1005b. Different implementations may use different spacing between the integrated devices.

Stage 4, as shown in FIG. 10B, illustrates a state after an encapsulation layer 501 is formed and coupled to the carrier 1007 and the plurality of integrated devices 1005. The encapsulation layer 501 may be located between the plurality of integrated devices 1005. In some implementations, the encapsulation layer 501 may be coupled to the back side of the plurality of integrated devices 1005. The thickness of the encapsulation layer 501 may be greater than thickness of the plurality of integrated devices 1005. The encapsulation layer 501 may include a mold, a resin and/or an epoxy. The encapsulation layer 501 may be a means for encapsulation. The encapsulation layer 501 may be provided by using a compression and transfer molding process, a sheet molding process, or a liquid molding process.

Stage 5 illustrates a state after portions of the encapsulation layer 501 are removed so that a surface of the encapsulation layer 501 is planar with the back side surface of the plurality of integrated devices 1005. For example, the surface of the die substrate 120 may be planar with the surface of the encapsulation layer 501. A grinding process and/or a polishing process may be used to planarize (e.g., remove portions of) the encapsulation layer 501. In some implementations, planarizing the encapsulation layer 501 may also include removing portions of the plurality of integrated devices 1005. For example, a planarization process (e.g., grinding process, polishing process) may remove portions of the die substrate 120 of the plurality of integrated devices 1005.

Stage 6, as shown in FIG. 10C, illustrates a state after the carrier 1007 is removed, leaving a reconstituted wafer 1009 that includes the plurality of integrated devices 1005 and the encapsulation layer 501. The carrier 1007 may be peeled off from the reconstituted wafer 1009.

Stage 7 illustrates a state after a seed layer 105 are formed over the reconstituted wafer 1009, The seed layer 105 may be formed over the passivation layer 106 and the plurality of pad interconnects 103. The seed layer 105 may include copper (Cu). A sputtering process may be used to form the seed layer 105.

Stage 8, as shown in FIG. 10D, illustrates a state after a photo resist layer 1010 is formed over the reconstituted wafer 1009. For example, the photo resist layer 1010 may be formed over the seed layer 105. The photo resist layer 1010 may be patterned to include a plurality of openings 1011 in the photo resist layer 1010. The photo resist layer 1010 may be coated over the reconstituted wafer 1009. A photolithography process may be used to form and define the pattern of the photo resist layer 1010. For example, an exposure process and development process may be used to form the plurality of openings 1011 in the photo resist layer 1010. The plurality of openings 1011 may be located over the plurality of pads 103.

Stage 9 illustrates a state after the plurality of metallization interconnects 107 are formed and coupled to the seed layer 105. The plurality of metallization interconnects 107 may be formed and coupled to the plurality of pad interconnects 103 through the seed layer 105. A plating process may be used to form the plurality of metallization interconnects 107. The plurality of metallization interconnects 107 may be formed in the plurality of openings 1011 of the photo resist layer 1010.

Stage 10, as shown in FIG. 10E, illustrates a state after the photo resist layer 1010 is removed. Stage 10 may also illustrate a state after portions of the seed layer 105 are removed. The remaining seed layer 105 may be considered part of the plurality of metallization interconnects 107. A strip process may be used to remove the photo resist layer 1010. An etching process may be used to selectively remove portions of the seed layer 105.

Stage 11 illustrates a state after a passivation layer 108. The passivation layer 108 may be formed over the reconstituted wafer 1009. For example, the passivation layer 108 may be formed over the passivation layer 106 and portions of the plurality of metallization interconnects 107. A deposition process, a lamination process, an exposure process and/or development process may be used to form the passivation layer 108.

Stage 12 illustrates a state after a photo resist layer 1020 is formed over the reconstituted wafer 1009. For example, the photo resist layer 1020 may be formed over the passivation layer 108. The photo resist layer 1020 may be patterned to include a plurality of openings 1021 in the photo resist layer 1020. The photo resist layer 1020 may be coated over the reconstituted wafer 1009. A photolithography process may be used to form and define the pattern of the photo resist layer 1020. For example, an exposure process and development process may be used to form the plurality of openings 1021 in the photo resist layer 1020. The plurality of openings 1021 may be located over the plurality of pads 103 and/or portions of the plurality of metallization interconnects 107.

Stage 13, as shown in FIG. 10F, illustrates a state after the plurality of pillar interconnects 109 are formed and coupled to the plurality of metallization interconnects 107. A plating process may be used to form the plurality of pillar interconnects 109. The plurality of pillar interconnects 109 may be formed in the plurality of openings 1021 of the photo resist layer 1020.

Stage 14 illustrates a state after the plurality of solder interconnects 190 are formed and coupled to the plurality of pillar interconnects 109. The plurality of solder interconnects 190 may be formed through the plurality of openings 1021 of the photo resist layer 1020. A pasting process may be used to form the plurality of solder interconnects 190.

Stage 15, as shown in FIG. 10G, illustrates a state after the photo resist layer 1020 is removed. A strip process may be used to remove the photo resist layer 1020. A solder reflow process may be performed, which couples the plurality of solder interconnects 190 to the plurality of pillar interconnects 109.

Stage 16 illustrates a state after singulation of the reconstituted wafer 1009 into individual integrated devices. The reconstituted wafer 1009 may be cut through the scribe region 802. A mechanical process (e.g., saw process) may be used to singulate the reconstituted wafer 1009. Singulation of the reconstituted wafer 1009 may be along a region that includes the encapsulation layer 501. After singulation, the integrated device 500 may be fabricated, where the integrated device 500 includes a pillar interconnect that is located in a periphery region of the integrated device 500 that is free of die interconnects and free of an active region.

### Exemplary Flow Diagram of a Method for Fabricating an Integrated Device

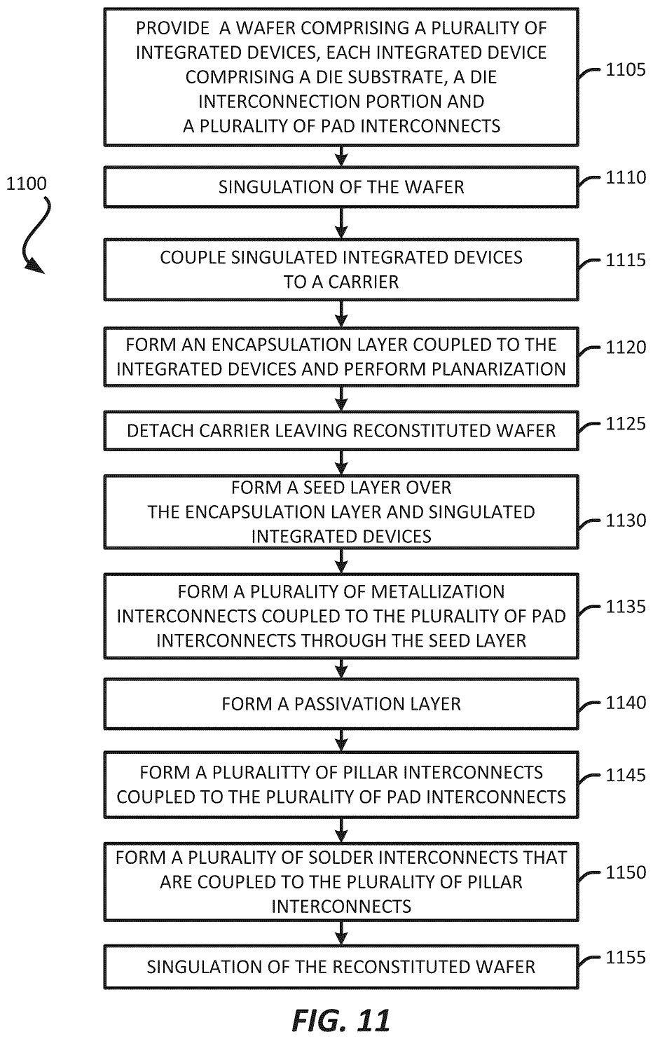

In some implementations, fabricating an integrated device includes several processes. FIG. 11 illustrates an exemplary flow diagram of a method 1100 for providing or fabricating an integrated device. In some implementations, the method 1100 of FIG. 11 may be used to provide or fabricate the integrated device 500 of FIG. 5 described in the disclosure. However, the method 1100 may be used to provide or fabricate any of the integrated devices described in the disclosure.

It should be noted that the method 1100 of FIG. 11 may combine one or more processes in order to simplify and/or clarify the method for providing or fabricating an integrated device. In some implementations, the order of the processes may be changed or modified.

The method provides (at 1105) a wafer that includes uncut integrated devices. Stage 1 of FIG. 10A, illustrates and describes an example of a state after a wafer 1000 is provided. The wafer 1000 may include a die substrate portion 102, a die interconnection portion 104, a die substrate 120, the active region 122, at least one dielectric layer 140, a plurality of die interconnects 142, a plurality of pad interconnects 103, a passivation layer 106. The wafer 1000 may include uncut integrated devices. The wafer 1000 includes scribe regions 802. The scribe regions 802 are regions where the wafer 1000 may be cut to singulate the wafer 800 into individual integrated devices. A FEOL process and a BEOL process may be used to fabricate the wafer 1000 that includes a plurality of uncut integrated devices.

The method singulates (at 1110) the wafer into individual integrated devices. Stage 2 of FIG. 10A, illustrates and describes an example of a state after the wafer 1000 is cut and/or singulate to form a plurality of integrated devices 1005 (e.g., semiconductor dies). The plurality of integrated devices 1005 may include an integrated device 1005a and an integrated device 1005b. Each integrated device may include a die substrate portion 102, a die interconnection portion 104, a plurality of pad interconnects 103 and a passivation layer 106. The wafer 1000 may be cut along the scribe regions 1002 of the wafer 1000. A mechanical process (e.g., saw process) may be used to singulate the wafer 1000.

The method couples (at 1115) the plurality of singulated integrated devices to a carrier. Stage 3 of FIG. 10A, illustrates and describes an example of a state after the plurality of integrated devices 1005 are placed and coupled to a carrier 1007. An adhesive (not shown) may be used to place and couple the plurality of integrated devices 1005 to the carrier 1007. There may be a space 1008 between the integrated devices. For example, there is a space 1008 between the integrated device 1005a and the integrated device 1005b. Different implementations may use different spacing between the integrated devices.

The method forms (at 1120) an encapsulation layer and perform planarization. Stage 4 of FIG. 10B, illustrates and describes an example of a state after an encapsulation layer 501 is formed and coupled to the carrier 1007 and the plurality of integrated devices 1005. The encapsulation layer 501 may be located between the plurality of integrated devices 1005. In some implementations, the encapsulation layer 501 may be coupled to the back side of the plurality of integrated devices 1005. The thickness of the encapsulation layer 501 may be greater than thickness of the plurality of integrated devices 1005. The encapsulation layer 501 may include a mold, a resin and/or an epoxy. The encapsulation layer 501 may be a means for encapsulation. The encapsulation layer 501 may be provided by using a compression and transfer molding process, a sheet molding process, or a liquid molding process.

Stage 5 of FIG. 10B, illustrates and describes an example of a state after portions of the encapsulation layer 501 are removed so that a surface of the encapsulation layer 501 is planar with the back side surface of the plurality of integrated devices 1005. For example, the surface of the die substrate 120 may be planar with the surface of the encapsulation layer 501. A grinding process and/or a polishing process may be used to planarize (e.g., remove portions of) the encapsulation layer 501. In some implementations, planarizing the encapsulation layer 501 may also include removing portions of the plurality of integrated devices 1005. For example, a planarization process (e.g., grinding process, polishing process) may remove portions of the die substrate 120 of the plurality of integrated devices 1005.

The method detaches (at 1125) the carrier from a reconstituted wafer. Stage 6 of FIG. 10C, illustrates and describes an example of a state after the carrier 1007 is removed, leaving a reconstituted wafer 1009 that includes the plurality of integrated devices 1005 and the encapsulation layer 501. The carrier 1007 may be peeled off from the reconstituted wafer 1009.

The method forms (at 1130) a seed layer to the reconstituted wafer. Stage 7 of FIG. 10C, illustrates and describes an example of a state after a seed layer 105 are formed over the reconstituted wafer 1009, The seed layer 105 may be formed over the passivation layer 106 and the plurality of pad interconnects 103. The seed layer 105 may include copper (Cu). A sputtering process may be used to form the seed layer 105.

The method forms (at 1135) a plurality of metallization interconnects. Stages 8 through 10 of FIGS. 10D-FIG. 10E illustrate and describe an example of forming a plurality of metallization interconnects.

Stage 8 of FIG. 10D, illustrates and describes an example of a state after a photo resist layer 1010 is formed over the reconstituted wafer 1009. For example, the photo resist layer 1010 may be formed over the seed layer 105. The photo resist layer 1010 may be patterned to include a plurality of openings 1011 in the photo resist layer 1010. The photo resist layer 1010 may be coated over the reconstituted wafer 1009. A photolithography process may be used to form and define the pattern of the photo resist layer 1010. For example, an exposure process and development process may be used to form the plurality of openings 1011 in the photo resist layer 1010. The plurality of openings 1011 may be located over the plurality of pads 103.

Stage 9 of FIG. 10D, illustrates and describes an example of a state after the plurality of metallization interconnects 107 are formed and coupled to the seed layer 105. The plurality of metallization interconnects 107 may be formed and coupled to the plurality of pad interconnects 103 through the seed layer 105. A plating process may be used to form the plurality of metallization interconnects 107. The plurality of metallization interconnects 107 may be formed in the plurality of openings 1011 of the photo resist layer 1010.

Stage 10 of FIG. 10E, illustrates and describes an example of a state after the photo resist layer 1010 is removed. Stage 10 may also illustrate a state after portions of the seed layer 105 are removed. The remaining seed layer 105 may be considered part of the plurality of metallization interconnects 107. A strip process may be used to remove the photo resist layer 1010. An etching process may be used to selectively remove portions of the seed layer 105.

The method forms (at 1140) a passivation layer. Stage 11 of FIG. 10E, illustrates and describes an example of a state after a passivation layer 108. The passivation layer 108 may be formed over the reconstituted wafer 1009. For example, the passivation layer 108 may be formed over the passivation layer 106 and portions of the plurality of metallization interconnects 107. A deposition process, a lamination process, an exposure process and/or development process may be used to form the passivation layer 108.

The method forms (at 1145) a plurality of pillar interconnects that are coupled to the plurality of metallization interconnects. Stages 12 through 13 of FIGS. 10E-10F, illustrate and describe an example of forming a plurality of pillar interconnects. Stage 12 of FIG. 10E, illustrates and describes an example of a state after a photo resist layer 1020 is formed over the reconstituted wafer 1009. For example, the photo resist layer 1020 may be formed over the passivation layer 108. The photo resist layer 1020 may be patterned to include a plurality of openings 1021 in the photo resist layer 1020. The photo resist layer 1020 may be coated over the reconstituted wafer 1009. A photolithography process may be used to form and define the pattern of the photo resist layer 1020. For example, an exposure process and development process may be used to form the plurality of openings 1021 in the photo resist layer 1020. The plurality of openings 1021 may be located over the plurality of pads 103 and/or portions of the plurality of metallization interconnects 107.

Stage 13 of FIG. 10F, illustrates and describes an example of a state after the plurality of pillar interconnects 109 are formed and coupled to the plurality of metallization interconnects 107. A plating process may be used to form the plurality of pillar interconnects 109. The plurality of pillar interconnects 109 may be formed in the plurality of openings 1021 of the photo resist layer 1020.

The method forms (at 1150) a plurality of solder interconnects to the plurality of plurality of pillar interconnects. Stage 14 of FIG. 10F, illustrates and describes an example of a state after the plurality of solder interconnects 190 are formed and coupled to the plurality of pillar interconnects 109. The plurality of solder interconnects 190 may be formed through the plurality of openings 1021 of the photo resist layer 1020. A pasting process may be used to form the plurality of solder interconnects 190.

In some implementations, once the plurality of solder interconnects 190 are formed, a photo resist layer may be removed. Stage 15 of FIG. 10G, illustrates and describes an example of a state after the photo resist layer 1020 is removed. A strip process may be used to remove the photo resist layer 1020. A solder reflow process may be performed, which couples the plurality of solder interconnects 190 to the plurality of pillar interconnects 109.

The method singulates (at 1155) the reconstituted wafer into individual integrated devices. Stage 16 of FIG. 10G, illustrates and describes an example of a state after singulation of the reconstituted wafer 1009 into individual integrated devices. The reconstituted wafer 1009 may be cut through the scribe region 802. A mechanical process (e.g., saw process) may be used to singulate the reconstituted wafer 1009. Singulation of the reconstituted wafer 1009 may be along a region that includes the encapsulation layer 501. After singulation, the integrated device 500 may be fabricated, where the integrated device 500 includes a pillar interconnect that is located in a periphery region of the integrated device 500 that is free of die interconnects and free of an active region.

### Exemplary Electronic Devices

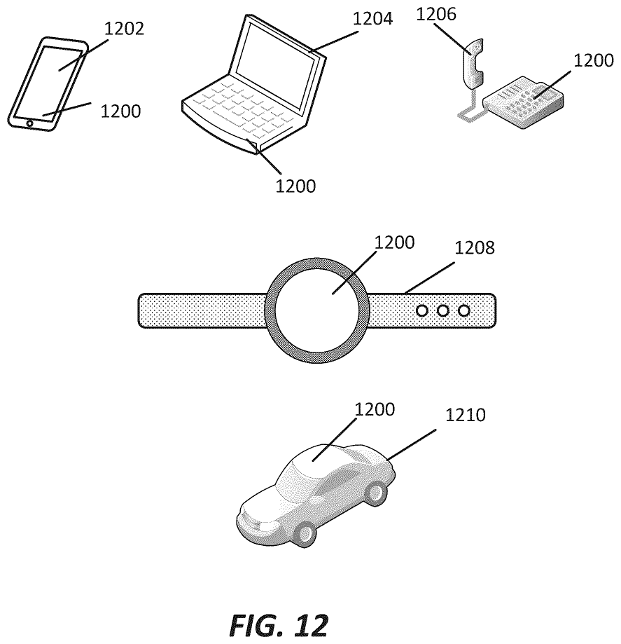

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1202, a laptop computer device 1204, a fixed location terminal device 1206, a wearable device 1208, or automotive vehicle 1210 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-7, 8A-8E, 9, 10A-10G and/or 11-12 may be rearranged and/or combined into a single component, process, feature or function or embodied in several components, processes, or functions. Additional elements, components, processes, and/or functions may also be added without departing from the disclosure. It should also be noted FIGS. 1-7, 8A-8E, 9, 10A-10G and/or 11-12 and its corresponding description in the present disclosure is not limited to dies and/or ICs. In some implementations, FIGS. 1-7, 8A-8E, 9, 10A-10G and/or 11-12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object that is coupled to another object may be coupled to at least part of the another object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: An integrated device comprising a die substrate; a die interconnection portion coupled to the die substrate. The die interconnection portion comprises at least one die dielectric layer; and a plurality of die interconnects, wherein the die interconnection portion comprises: an inner die interconnection portion; and a periphery die interconnection portion, wherein the periphery die interconnect portion is free of the plurality of die interconnects; a plurality of pad interconnects coupled to the die interconnection portion; a plurality of metallization interconnects coupled to the plurality of pad interconnects, wherein at least one metallization interconnect from the plurality of metallization interconnects, vertically overlaps with the periphery die interconnection portion, and a plurality of pillar interconnects coupled to the plurality of metallization interconnects.

Aspect 2: The integrated device of aspect 1, wherein the plurality of pillar interconnects comprise a first pillar interconnect that vertically overlaps with the periphery die interconnection portion; and a second pillar interconnect that vertically overlaps with the inner die interconnection portion.

Aspect 3: The integrated device of aspect 2, wherein the first pillar interconnect does not vertically overlap with the plurality of die interconnects.

Aspect 4: The integrated device of aspects 2 through 3, wherein the integrated device comprises an inner region; and a periphery region, wherein the inner die interconnection portion is part of the inner region of the integrated device, and wherein the periphery die interconnection portion is part of the periphery region of the integrated device.

Aspect 5: The integrated device of aspect 4, wherein the plurality of pad interconnects comprise a first pad interconnect and a second pad interconnect, wherein the first pad interconnect and the second pad interconnect are located in the inner region of the integrated device, wherein the plurality of metallization interconnects comprise a first metallization interconnect and a second metallization interconnect, wherein the first pillar interconnect is coupled to the first pad interconnect through the first metallization interconnect, and wherein the second pillar interconnect is coupled to the second pad interconnect through the second metallization interconnect.

Aspect 6: The integrated device of aspect 4, wherein the plurality of pad interconnects comprise a first pad interconnect, a second pad interconnect, and a third pad interconnect wherein the second pad interconnect and the third pad interconnect are located in the inner region of the integrated device, wherein the first pad interconnect is located in the periphery region of the integrated device, wherein the plurality of metallization interconnects comprise a first metallization interconnect and a second metallization interconnect, wherein the first pillar interconnect is coupled to the first pad interconnect through the first metallization interconnect, wherein the first metallization interconnect is coupled to the first pad interconnect and the third pad interconnect, and wherein the second pillar interconnect is coupled to the second pad interconnect through the second metallization interconnect.

Aspect 7: The integrated device of aspect 4, wherein the die substrate includes an active region comprising a plurality of logic cells, wherein the active region is located in the inner region of the integrated device, and wherein the periphery region is free of any logic cells.

Aspect 8: The integrated device of aspect 7, wherein at least one pillar interconnect does not vertically overlap with the active region.

Aspect 9: The integrated device of aspects 1 through 8, further comprising a seed layer that is part of the plurality of metallization interconnects.

Aspect 10: The integrated device of aspects 1 through 9, further comprising a plurality of solder interconnects coupled to the plurality of pillar interconnects.

Aspect 11: An integrated device comprising a die substrate; a die interconnection portion coupled to the die substrate, wherein the die interconnection portion comprises: at least one die dielectric layer; and a plurality of die interconnects, a plurality of pad interconnects coupled to the die interconnection portion; an encapsulation layer coupled to (i) a side surface of the die substrate and (ii) a side surface of the die interconnection portion; a plurality of metallization interconnects coupled to the plurality of pad interconnects, wherein at least one metallization interconnect from the plurality of metallization interconnect vertically overlaps with the encapsulation layer, and a plurality of pillar interconnects coupled to the plurality of metallization interconnects.

Aspect 12: The integrated device of aspect 11, wherein the plurality of pillar interconnects comprise a first pillar interconnect that vertically overlaps with the encapsulation layer; and a second pillar interconnect that vertically overlaps with the die interconnection portion.

Aspect 13: The integrated device of aspect 12, wherein the first pillar interconnect does not vertically overlap with the plurality of die interconnects.

Aspect 14: The integrated device of aspects 12 through 13, wherein the integrated device comprises an inner region; and a periphery region, wherein the die interconnection portion is part of the inner region of the integrated device, and wherein the encapsulation layer is part of the periphery region of the integrated device.

Aspect 15: The integrated device of aspect 14, wherein the plurality of pad interconnects comprise a first pad interconnect and a second pad interconnect, wherein the first pad interconnect and the second pad interconnect are located in the inner region of the integrated device, wherein the plurality of metallization interconnects comprise a first metallization interconnect and a second metallization interconnect, wherein the first pillar interconnect is coupled to the first pad interconnect through the first metallization interconnect, and wherein the second pillar interconnect is coupled to the second pad interconnect through the second metallization interconnect.

Aspect 16: The integrated device of aspect 14, wherein the plurality of pad interconnects comprise a first pad interconnect, a second pad interconnect, and a third pad interconnect wherein the second pad interconnect and the third pad interconnect are located in the inner region of the integrated device, wherein the first pad interconnect is located in the periphery region of the integrated device, wherein the plurality of metallization interconnects comprise a first metallization interconnect and a second metallization interconnect, wherein the first pillar interconnect is coupled to the first pad interconnect through the first metallization interconnect, wherein the first metallization interconnect is coupled to the first pad interconnect and the third pad interconnect, and wherein the second pillar interconnect is coupled to the second pad interconnect through the second metallization interconnect.

Aspect 17: The integrated device of aspect 14, wherein the die substrate includes an active region comprising a plurality of logic cells, wherein the active region is located in the inner region of the integrated device, and wherein the periphery region is free of any logic cells.

Aspect 18: The integrated device of aspect 17, wherein at least one pillar interconnect does not vertically overlap with the active region.

Aspect 19: The integrated device of aspects 11 through 18, further comprising a seed layer that is part of the plurality of metallization interconnects.

Aspect 20: The integrated device of aspect 11 through 19, further comprising a plurality of solder interconnects coupled to the plurality of pillar interconnects.

Aspect 21: The integrated device of aspects 11 through 20, wherein the integrated device is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 22: The integrated device of aspects 1 through 10, wherein the integrated device is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die substrate;
a die interconnection portion coupled to the die substrate, wherein the die interconnection portion comprises:
at least one die dielectric layer; and
a plurality of die interconnects,
wherein the die interconnection portion comprises:
an inner die interconnection portion; and
a periphery die interconnection portion, wherein the periphery die interconnect portion is free of the plurality of die interconnects;
a plurality of pad interconnects coupled to the die interconnection portion;
a plurality of metallization interconnects coupled to the plurality of pad interconnects, wherein at least one metallization interconnect from the plurality of metallization interconnects, vertically overlaps with the periphery die interconnection portion, and
a plurality of pillar interconnects coupled to the plurality of metallization interconnects.

2. The integrated device of claim 1, wherein the plurality of pillar interconnects comprise:
a first pillar interconnect that vertically overlaps with the periphery die interconnection portion; and
a second pillar interconnect that vertically overlaps with the inner die interconnection portion.

3. The integrated device of claim 2, wherein the first pillar interconnect does not vertically overlap with the plurality of die interconnects.

4. The integrated device of claim 2,
wherein the integrated device comprises:
an inner region; and
a periphery region,
wherein the inner die interconnection portion is part of the inner region of the integrated device, and
wherein the periphery die interconnection portion is part of the periphery region of the integrated device.

5. The integrated device of claim 4,
wherein the plurality of pad interconnects comprise a first pad interconnect and a second pad interconnect,
wherein the first pad interconnect and the second pad interconnect are located in the inner region of the integrated device,
wherein the plurality of metallization interconnects comprise a first metallization interconnect and a second metallization interconnect,
wherein the first pillar interconnect is coupled to the first pad interconnect through the first metallization interconnect, and
wherein the second pillar interconnect is coupled to the second pad interconnect through the second metallization interconnect.

6. The integrated device of claim 4,
wherein the plurality of pad interconnects comprise a first pad interconnect, a second pad interconnect, and a third pad interconnect
wherein the second pad interconnect and the third pad interconnect are located in the inner region of the integrated device,
wherein the first pad interconnect is located in the periphery region of the integrated device,
wherein the plurality of metallization interconnects comprise a first metallization interconnect and a second metallization interconnect,
wherein the first pillar interconnect is coupled to the first pad interconnect through the first metallization interconnect,
wherein the first metallization interconnect is coupled to the first pad interconnect and the third pad interconnect, and
wherein the second pillar interconnect is coupled to the second pad interconnect through the second metallization interconnect.

7. The integrated device of claim 4,
wherein the die substrate includes an active region comprising a plurality of logic cells,
wherein the active region is located in the inner region of the integrated device, and
wherein the periphery region is free of any logic cells.

8. The integrated device of claim 7, wherein at least one pillar interconnect does not vertically overlap with the active region.

9. The integrated device of claim 1, further comprising a seed layer that is part of the plurality of metallization interconnects.

10. The integrated device of claim 1, further comprising a plurality of solder interconnects coupled to the plurality of pillar interconnects.

11. An integrated device comprising:
a die substrate;
a die interconnection portion coupled to the die substrate, wherein the die interconnection portion comprises:
at least one die dielectric layer; and
a plurality of die interconnects,
a plurality of pad interconnects coupled to the die interconnection portion;
an encapsulation layer coupled to (i) a side surface of the die substrate and (ii) a side surface of the die interconnection portion;
a plurality of metallization interconnects coupled to the plurality of pad interconnects, wherein at least one metallization interconnect from the plurality of metallization interconnect vertically overlaps with the encapsulation layer, and
a plurality of pillar interconnects coupled to the plurality of metallization interconnects.

12. The integrated device of claim 11, wherein the plurality of pillar interconnects comprise:
a first pillar interconnect that vertically overlaps with the encapsulation layer; and
a second pillar interconnect that vertically overlaps with the die interconnection portion.

13. The integrated device of claim 12, wherein the first pillar interconnect does not vertically overlap with the plurality of die interconnects.

14. The integrated device of claim 12,
wherein the integrated device comprises:
an inner region; and
a periphery region,
wherein the die interconnection portion is part of the inner region of the integrated device, and
wherein the encapsulation layer is part of the periphery region of the integrated device.

15. The integrated device of claim 14,
wherein the plurality of pad interconnects comprise a first pad interconnect and a second pad interconnect,
wherein the first pad interconnect and the second pad interconnect are located in the inner region of the integrated device,
wherein the plurality of metallization interconnects comprise a first metallization interconnect and a second metallization interconnect,
wherein the first pillar interconnect is coupled to the first pad interconnect through the first metallization interconnect, and
wherein the second pillar interconnect is coupled to the second pad interconnect through the second metallization interconnect.

16. The integrated device of claim 14,
wherein the plurality of pad interconnects comprise a first pad interconnect, a second pad interconnect, and a third pad interconnect
wherein the second pad interconnect and the third pad interconnect are located in the inner region of the integrated device,
wherein the first pad interconnect is located in the periphery region of the integrated device,
wherein the plurality of metallization interconnects comprise a first metallization interconnect and a second metallization interconnect,
wherein the first pillar interconnect is coupled to the first pad interconnect through the first metallization interconnect,
wherein the first metallization interconnect is coupled to the first pad interconnect and the third pad interconnect, and
wherein the second pillar interconnect is coupled to the second pad interconnect through the second metallization interconnect.

17. The integrated device of claim 14,
wherein the die substrate includes an active region comprising a plurality of logic cells,
wherein the active region is located in the inner region of the integrated device, and
wherein the periphery region is free of any logic cells.

18. The integrated device of claim 17, wherein at least one pillar interconnect does not vertically overlap with the active region.

19. The integrated device of claim 11, further comprising a seed layer that is part of the plurality of metallization interconnects.

20. The integrated device of claim 11, further comprising a plurality of solder interconnects coupled to the plurality of pillar interconnects.
